(19) United States
(12) Patent Application Publication
(10) Pub. No.: US 2026/0255819 A1
(43) Pub. Date: Aug. 27, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Bangqing XIAO, Beijing (CN); Benlian WANG, Beijing (CN); Hai ZHENG, Beijing (CN); Weiyun HUANG, Beijing (CN)

(21) Appl. No.: 18/995,193

(22) PCT Filed: Apr. 28, 2024
(86) PCT No.: PCT/CN2024/090284

§ 371 Date: Jan. 16, 2025

(30) Foreign Application Priority Data
May 31, 2023 (CN) 202310639739.6

(51) Int. Cl. H10K 59/131

(52) U.S. Cl. CPC H10K 59/131

(57) ABSTRACT

A display substrate, comprising a base substrate, a driving circuit layer and a light-emitting structure layer. The driving circuit layer comprises multiple first circuit units and multiple second circuit units. Each first circuit unit comprises a first pixel circuit, and a scanning line and a first data line that are electrically connected to the first pixel circuit. Each second circuit unit comprises an invalid pixel circuit, and the scanning line and an invalid data line that are electrically connected to the invalid pixel circuit. The display substrate satisfies at least one of: overlapping area of scanning lines and first pixel circuits in the first circuit units is larger than that of scanning lines and invalid pixel circuits in the second circuit units, overlapping area of scanning lines and first data lines in first circuit units is larger than that of scanning lines and invalid data lines in second circuit units.

### CROSS-REFERENCE TO RELATED APPLICATIONS

The present application is a U.S. National Phase Entry of International Application No. PCT/CN2024/090284 having an international filing date of Apr. 28, 2024, which claims the priority to Chinese Patent Application No. 202310639739.6, filed on May 31, 2023, to the China National Intellectual Property Administration, the contents of which should be regarded as being incorporated herein by reference in their entireties.

### TECHNICAL FIELD

The present disclosure relates to, but is not limited to, the field of display technologies, in particular to a display substrate and a display apparatus.

### BACKGROUND

Organic Light Emitting Diodes (OLED) and Quantum-dot Light Emitting Diodes (QLED) are active light emitting display devices, and have advantages of self-illumination, a wide viewing angle, a high contrast ratio, low power consumption, an extremely high reaction speed, lightness and thinness, flexibility, and low cost, etc. An under display camera technology is a brand-new technology proposed to increase a screen-to-body ratio of a display device.

### SUMMARY

The following is a summary of subject matters described herein in detail. This summary is not intended to limit the protection scope of claims.

Embodiments of the present disclosure provide a display substrate and a display apparatus.

In one aspect, an embodiment of the present disclosure provides a display substrate, including a base substrate, a drive circuit layer and light emitting structure layer. The drive circuit layer is located in the first display region and including: a plurality of circuit units constituting a plurality of unit rows and a plurality of unit columns; the plurality of circuit units includes at least: a plurality of first circuit units and a plurality of second circuit units; a first circuit unit includes: a first pixel circuit and a scan line extending in a first direction and a first data line extending in a second direction electrically connected to the first pixel circuit; at least one of the second circuit units includes: a dummy pixel circuit and the scan line and a dummy data line extending in the second direction electrically connected to the dummy pixel circuit; the first direction intersects the second direction. The light emitting structure layer is located on a side of the drive circuit layer away from the base substrate, including a plurality of first light emitting elements located in the first display region, and at least one of the first pixel circuits is electrically connected to at least one of the first light emitting elements. The display substrate satisfies at least one of: an overlapping area of the scan line with the first pixel circuit within the first circuit unit is larger than an overlapping area of the scan line with the dummy pixel circuit within the second circuit unit; an overlapping area of the scan line with the first data line within the first circuit unit is larger than an overlapping area of the scan line with the dummy data line within the second circuit unit.

In some exemplary implementation modes, orthographic projections of the scan line and the dummy data line within the second circuit unit on the base substrate do not overlap.

In some exemplary implementation modes, in a unit column where the second circuit unit is located, a plurality of dummy data lines are sequentially arranged in the second direction, a first fracture is provided between dummy data lines adjacent in the second direction, and a length of the scan line along the second direction is smaller than a length of the first fracture along the second direction.

In some exemplary implementation modes, the dummy data line in the second circuit unit is electrically connected to a second voltage line extending in the second direction and transmitting a first voltage signal.

In some exemplary implementation modes, in a direction perpendicular to the display substrate, the drive circuit layer includes: a semiconductor layer, a first conductive layer, a second conductive layer, a third conductive layer, a fourth conductive layer, and a fifth conductive layer disposed on the base substrate. The scan line is located in the first conductive layer, the dummy data line and the first data line are located in the fifth conductive layer, and the second voltage line is located in the third conductive layer.

In some exemplary implementation modes, the dummy data line in the second circuit unit is electrically connected to a third voltage line extending in the first direction and transmitting a second voltage signal.

In some exemplary implementation modes, the drive circuit layer further includes: a fourth voltage line extending in the second direction and transmitting the second voltage signal, the fourth voltage line is located at a side of the third voltage line away from the base substrate and electrically connected to the third voltage line; the dummy data line and the fourth voltage line are disposed in a same layer.

In some exemplary implementation modes, in a direction perpendicular to the display substrate, the drive circuit layer includes: a semiconductor layer, a first conductive layer, a second conductive layer, a third conductive layer, a fourth conductive layer, and a fifth conductive layer disposed on the base substrate. The third voltage line is located in the fourth conductive layer, and the dummy data line and the fourth voltage line are located in the fifth conductive layer.

In some exemplary implementation modes, the first pixel circuit and the dummy pixel circuit both include at least: a drive transistor, a data writing transistor, and a threshold compensation transistor; gates of the data writing transistor and the threshold compensation transistor of the first pixel circuit and the dummy pixel circuit are electrically connected to the scan line. A first electrode of the data writing transistor of the first pixel circuit is electrically connected to the first data line, and a second electrode of the data writing transistor of the first pixel circuit is electrically connected to a first electrode of the drive transistor of the first pixel circuit; a first electrode of the threshold compensation transistor of the first pixel circuit is electrically connected to a gate of the drive transistor of the first pixel circuit, and a second electrode of the threshold compensation transistor of the first pixel circuit is electrically connected to a second electrode of the drive transistor of the first pixel circuit. A first electrode of the data writing transistor of the dummy pixel circuit is electrically connected to the dummy data line, and a second electrode of the data writing transistor of the dummy pixel circuit is electrically connected to a first electrode of the drive transistor of the dummy pixel circuit; a first electrode of the threshold compensation transistor of the dummy pixel circuit is electrically connected to a gate of the drive transistor of the dummy pixel circuit, and a second electrode of the threshold compensation transistor of the dummy pixel circuit is electrically connected to a second electrode of the drive transistor of the dummy pixel circuit. The display substrate satisfies at least one of the following: the threshold compensation transistor of the first pixel circuit has a dual-gate structure, and the threshold compensation transistor of the dummy pixel circuit has a single-gate structure; a length of a gate of the data writing transistor of the first pixel circuit along the second direction is greater than a length of a gate of the data writing transistor of the dummy pixel circuit along the second direction.

In some exemplary implementation modes, gates of the data writing transistor and the threshold compensation transistor of the first pixel circuit and the dummy pixel circuit and the scan line are of an interconnected integral structure.

In some exemplary implementation modes, the first pixel circuit and the dummy pixel circuit both include: a drive transistor, a first reset transistor, a threshold compensation transistor, and a storage capacitor. A gate of the drive transistor, a second electrode of the first reset transistor, a first electrode of the threshold compensation transistor and a first plate of the storage capacitor of the first pixel circuit are electrically connected with a second connection electrode; an orthographic projection of the second connection electrode on the base substrate is partially overlapped with an orthographic projection of the scan line on the base substrate. A gate of the drive transistor and a first plate of the storage capacitor of the dummy pixel circuit are electrically connected to a ninth connection electrode, a second electrode of the first reset transistor and a first electrode of the threshold compensation transistor of the dummy pixel circuit are electrically connected to a tenth connection electrode, and the ninth connection electrode and the tenth connection electrode are located at two sides of the scan line and orthographic projections of the ninth connection electrode and the tenth connection electrode on the base substrate do not overlap with the orthographic projection of the scan line on the base substrate.

In some exemplary implementation modes, the ninth connection electrode and the tenth connection electrode are both electrically connected to a second voltage line extending in the second direction and transmitting a first voltage signal.

In some exemplary implementation modes, the first pixel circuit further includes: a first shielding electrode located at a side of the second connection electrode away from the base substrate, an orthographic projection of the first shielding electrode on the base substrate covers an orthographic projection of the second connection electrode on the base substrate. The dummy pixel circuit further includes a second shielding electrode located at a side of the ninth connection electrode and the tenth connection electrode away from the base substrate, and an orthographic projection of the second shielding electrode on the base substrate covers orthographic projections of the ninth connection electrode and the tenth connection electrode on the base substrate.

In some exemplary implementation modes, the first pixel circuit further includes: a first shielding electrode located at a side of the second connection electrode away from the base substrate, an orthographic projection of the first shielding electrode on the base substrate covers an orthographic projection of the second connection electrode on the base substrate. The dummy pixel circuit further includes: a third shielding electrode and a fourth shielding electrode located at a side of the ninth connection electrode and the tenth connection electrode away from the base substrate; an orthographic projection of the third shielding electrode on the base substrate covers an orthographic projection of the ninth connection electrode on the base substrate, an orthographic projection of the fourth shielding electrode on the base substrate covers an orthographic projection of the tenth connection electrode on the base substrate, and orthographic projections of the third shielding electrode and the fourth shielding electrode on the base substrate do not overlap with the orthographic projection of the scan line on the base substrate.

In some exemplary implementation modes, the third shielding electrode is electrically connected to a third voltage line extending in the first direction and transmitting a second voltage signal; the fourth shielding electrode is electrically connected to a second voltage line extending in the second direction and transmitting a first voltage signal, and the first voltage signal is greater than the second voltage signal.

In some exemplary implementation modes, the plurality of circuit units further includes: a plurality of second pixel circuits; at least one of the second pixel circuits and the dummy pixel circuit are located in a same unit column. The base substrate further includes: a second display region located on at least one side of the first display region; the light emitting structure layer further includes: a plurality of second light emitting elements located in the second display region. At least one of the second pixel circuits is connected with at least one second light emitting element through a conductive connection line.

In another aspect, the present disclosure provides a display apparatus, including the display substrate described above, and a sensor located on a non-display side of the display substrate; an orthographic projection of the sensor on the display substrate is at least partially overlapped with a second display region of the display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure.

FIG. 1 is a schematic diagram of a display substrate according to at least one embodiment of the present disclosure.

FIG. 2 is a schematic structural plan view of a display region of a display substrate according to at least one embodiment of the present disclosure.

FIG. 3 is a schematic diagram of a partial structure of a display substrate according to at least one embodiment of the present disclosure.

FIG. 4 is an equivalent circuit diagram of a pixel circuit according to at least one embodiment of the present disclosure.

FIG. 5 is a schematic partial plan view of a firs display region according to at least one embodiment of the present disclosure.

FIG. 6 is a schematic plan diagram of the display substrate after a semiconductor layer is formed in FIG. 5.

FIG. 7A is a schematic plan view of the display substrate after a first conductive layer is formed in FIG. 5.

FIG. 7B is a schematic diagram of the first conductive layer in FIG. 7A.

FIG. 8A is a schematic plan view of the display substrate after a second conductive layer is formed in FIG. 5.

FIG. 8B is a schematic diagram of the second conductive layer in FIG. 8A.

FIG. 9 is a schematic plan view of a display substrate after a third insulating layer is formed in FIG. 5.

FIG. 10A is a schematic plan view of the display substrate after a third conductive layer is formed in FIG. 5.

FIG. 10B is a schematic diagram of the third conductive layer in FIG. 10A.

FIG. 11 is a schematic plan diagram of a display substrate after a fifth insulating layer is formed in FIG. 5.

FIG. 12A is a schematic plan view of the display substrate after a fourth conductive layer in FIG. 5 is formed.

FIG. 12B is a schematic diagram of the fourth conductive layer in FIG. 12A.

FIG. 13 is a schematic plan view of a display substrate after a sixth insulating layer is formed in FIG. 5.

FIG. 14A is a schematic plan view of a display substrate after a fifth conductive layer is formed in FIG. 5.

FIG. 14B is a schematic diagram of the fifth conductive layer in FIG. 14A.

FIG. 15 is a schematic plan view of a display substrate after a seventh insulating layer is formed in FIG. 5.

FIG. 16A is a schematic plan view of the display substrate after a first connection layer is formed in FIG. 5.

FIG. 16B is a schematic diagram of the first connection layer in FIG. 16A.

FIG. 17 is a schematic plan view of a display substrate after an eighth insulating layer is formed in FIG. 5.

FIG. 18A is a schematic plan view of the display substrate after a second connection layer is formed in FIG. 5.

FIG. 18B is a schematic diagram of the second connection layer in FIG. 18A.

FIG. 19 is a schematic plan view of a display substrate after a ninth insulating layer is formed in FIG. 5.

FIG. 20A is a schematic plan view of the display substrate after a third connection layer is formed in FIG. 5.

FIG. 20B is a schematic diagram of the third connection layer in FIG. 20A.

FIG. 21 is a schematic plan view of a display substrate after a tenth insulating layer is formed in FIG. 5.

FIG. 22A is a schematic plan diagram of the display substrate after an anode layer is formed in FIG. 5.

FIG. 22B is a schematic diagram of the anode layer in FIG. 22A.

FIG. 23 is another schematic partial plan view of a drive circuit layer of a first display region of a display substrate according to at least one embodiment of the present disclosure.

FIG. 24A is a schematic plan view of the display substrate after a third conductive layer is formed in FIG. 23.

FIG. 24B is a schematic diagram of the third conductive layer in FIG. 24A.

FIG. 25A is a schematic plan view of the display substrate after a fourth conductive layer is formed in FIG. 23.

FIG. 25B is a schematic diagram of the fourth conductive layer in FIG. 25A.

FIG. 26 is another schematic partial plan view of a drive circuit layer of a first display region of a display substrate according to at least one embodiment of the present disclosure.

FIG. 27A is a schematic plan view of the display substrate after a third conductive layer is formed in FIG. 26.

FIG. 27B is a schematic diagram of the third conductive layer in FIG. 27A.

FIG. 28 is a schematic plan view of a display substrate after a fourth conductive layer is formed in FIG. 26.

FIG. 29 is another schematic partial plan view of a drive circuit layer of a first display region of a display substrate according to at least one embodiment of the present disclosure.

FIG. 30 is a schematic diagram of the first conductive layer in FIG. 29.

FIG. 31 is another schematic partial plan view of a drive circuit layer of a first display region of a display substrate according to at least one embodiment of the present disclosure.

FIG. 32 is another schematic partial plan view of a drive circuit layer of a first display region of a display substrate according to at least one embodiment of the present disclosure.

FIG. 33A is a schematic plan view of the display substrate after a third conductive layer is formed in FIG. 32.

FIG. 33B is a schematic diagram of the third conductive layer in FIG. 33A.

FIG. 34 is a schematic diagram of a fourth conductive layer in FIG. 32.

FIG. 35 is a schematic diagram of a display apparatus according to at least one embodiment of the present disclosure.

### DETAILED DESCRIPTION

The embodiments of the present disclosure will be described below with reference to the drawings in detail. Implementations may be implemented in multiple different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements are changed as appropriate according to directions of the constituent elements described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, an “electrical connection” includes a case that constituent elements are connected together through an element with a certain electrical action. The “element with a certain electrical effect” is not particularly limited as long as electrical signals between the connected constituent elements may be transmitted. Examples of the “element with a certain electrical effect” not only include an electrode and a wiring, but also include a switching element such as a transistor, a resistor, an inductor, a capacitor, and other elements with a plurality of functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, the gate may also be referred to as a control electrode.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

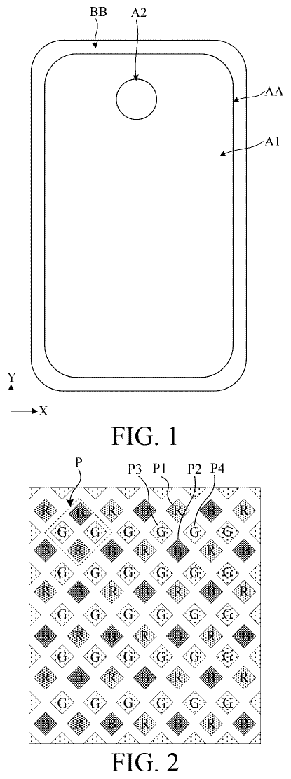

FIG. 1 is a schematic diagram of a display substrate according to at least one embodiment of the present disclosure. In some examples, as shown in FIG. 1, the display substrate may include a display region AA, and a peripheral region BB surrounding a periphery of the display region AA. The display region AA of the display substrate may include: a first display region Al and a second display region A2; the first display region A1 may at least partially surround the second display region A2. For example, the second display region A2 may be located in the middle of the top of the display region AA, and the first display region A1 may surround the second display region A2. However, the present embodiment is not limited thereto. For example, the second display region A2 may be located at another position such as the upper left corner or the upper right corner of the display region, and the first display region A1 may surround at least one side of the second display region A2.

In some examples, as shown in FIG. 1, the display region AA may be in a shape of a rectangle, e.g., a rounded rectangle. The second display region A2 may be circular or elliptical. However, the present embodiment is not limited thereto. For example, the second display region A2 may be rectangular, semi-circular, pentagonal, or in another shape.

In some examples, as shown in FIG. 1, the second display region A2 may be a light transmitting display region, and may also be called an FDC (Full Display with Camera) region configured for image display and light transmission, the first display region A1 may be a normal display region configured to perform image display. For example, an orthographic projection of a sensor (such as a camera and other hardware) on the display substrate may be located within the second display region A2 of the display substrate. In some examples, as shown in FIG. 1, the second display region A2 may be circular, and a dimension of an orthographic projection of the sensor on the display substrate may be less than or equal to a dimension of the second display region A2. However, the present embodiment is not limited thereto. In some other examples, the second display region A2 may be rectangular, and a dimension of an orthographic projection of the sensor on the display substrate may be less than or equal to a dimension of an inscribed circle of the second display region A2.

In some examples, as shown in FIG. 1, a ratio of the resolution of the second display region A2 to the resolution of the first display region A1 may be about 0.8 to 1.2. Or, the resolution of the second display region A2 is approximately the same as that of the first display region A1. The present embodiment is not limited thereto.

FIG. 2 is a schematic structural plan view of a display region of a display substrate according to at least one embodiment of the present disclosure. In some examples, as shown in FIG. 2, the display region may include a plurality of pixel units P, and at least one pixel unit P may include a first sub-pixel P1 that emits light of a first color, a second sub-pixel P2 that emits light of a second color, and a third sub-pixel P3 and a fourth sub-pixel P4 that emit light of a third color. In some examples, the first sub-pixel PI may be a red (R) sub-pixel emitting red light, the second sub-pixel P2 may be a blue (B) sub-pixel emitting blue light, and the third sub-pixel P3 and the fourth sub-pixel P4 may be a green (G) sub-pixels emitting green light.

In some examples, each sub-pixel may include a circuit unit and a light emitting element, the circuit unit may at least include a pixel circuit which is connected with a scan line, a data line, and a light emitting control line respectively, and the pixel circuit may be configured to receive a data voltage transmitted by the data line and output a corresponding current to the light emitting element under control of the scan line and the light emitting control line. The light emitting element in at least one sub-pixel is connected to a pixel circuit of a sub-pixel where the light emitting element is located, and is configured to emit light with a corresponding brightness in response to a current output by the pixel circuit of the sub-pixel where the light emitting element is located.

In some examples, the pixel circuit may include multiple transistors and at least one capacitor. For example, the pixel circuit may have a 3T1C, 4T1C, 5T1C, 5T2C, 6T1C, 7T1C, or 8T1C structure. In the aforementioned circuit structures, T refers to a thin film transistor, C refers to a capacitor, a digit before T represents a quantity of thin film transistors in the circuit, and a digit before C represents a quantity of capacitors in the circuit.

In some examples, the multiple transistors in the pixel circuit may be P-type transistors or may be N-type transistors. Usage of same type of transistors in the pixel circuit may simplify a process flow, reduce a process difficulty of the display substrate, and improve a yield of a product. In some other examples, the multiple transistors in the pixel circuit may include a P-type transistor and an N-type transistor.

In some examples, low temperature poly silicon thin film transistors, or oxide thin film transistors, or both a low temperature poly silicon thin film transistor(s) and an oxide thin film transistor(s) may be used as the plurality of transistors in the pixel circuit. Low Temperature Poly Silicon (LTPS) is adopted for an active layer of a low temperature poly silicon thin film transistor and an oxide semiconductor (Oxide) is adopted for an active layer of an oxide thin film transistor. The low temperature poly-silicon thin film transistor has advantages such as high migration rate and fast charging, and the oxide thin film transistor has advantages such as low leakage current. The low temperature poly-silicon thin film transistor and the oxide thin film transistor are integrated on one display substrate, that is, an LTPS+Oxide (LTPO) display substrate, advantages of both the low temperature poly-silicon thin film transistor and the oxide thin film transistor may be utilized, so that low-frequency drive can be achieved, power consumption can be reduced, and display quality can be improved.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, or the like under driving of a pixel circuit corresponding to the light emitting element. A color of light emitted by the light emitting element may be determined as needed. In some examples, the light emitting element may include an anode, a cathode, and an organic light emitting layer located between the anode and the cathode. The anode of the light emitting element may be electrically connected to a corresponding pixel circuit. However, the present embodiment is not limited thereto.

In some examples, a shape of the light emitting element may be a rectangle, a rhombus, a pentagon, or a hexagon. Light emitting elements of the four sub-pixels of one pixel unit may be arranged side by side horizontally, side by side vertically, or in a square arrangement. However, the present embodiment is not limited thereto. In other examples, one pixel unit may include three sub-pixels, light emitting elements of the three sub-pixels may be arranged side by side horizontally, side by side vertically, or in a manner like a Chinese character ″ “.

In some implementation modes, in order to improve a light transmittance of the second display region A2, only the light emitting element may be arranged in the second display region A2, and the pixel circuit for driving the light emitting element of the second display region A2 is arranged in the first display region A1. That is, the light transmittance of the second display region A2 is improved by separately arranging the light emitting element and the pixel circuit. In this embodiment, the light emitting element of the second display region is electrically connected to the pixel circuit of the first display region by a transparent conductive line, and the transparent conductive line may overlap with other signal traces (such as a scan line). For example, the parasitic capacitance generated by the overlap of the transparent conductive line and the scan line causes an increase in the load of the scan line, resulting in a decrease in the charging time of the pixel circuit, and a tendency to display poorly in a lateral direction (for example, in the first direction X) on both sides of the second display region. For example, a display brightness of the second display region is smaller than a display brightness of an adjacent region; a display brightness of the first display region close to the second display region is smaller than a display brightness of the first display region away from the second display region.

The present embodiment provides a display substrate and a display apparatus capable of improving a lateral poor display occurring in the display substrate.

The present embodiment provides a display substrate including a base substrate, a drive circuit layer, and a light emitting structure layer. The drive circuit layer is located in a first display region and includes: a plurality of circuit units constituting a plurality of unit rows and a plurality of unit columns; the plurality of circuit units includes at least a plurality of first circuit units and a plurality of second circuit units. A first circuit unit includes: a first pixel circuit and a scan line extending in a first direction and a first data line extending in a second direction electrically connected to the first pixel circuit; a second circuit unit includes a dummy pixel circuit and the scan line and a dummy data line extending in the second direction electrically connected to the dummy pixel circuit. The first direction intersects with the second direction. For example, the first direction and the second direction are perpendicular to each other. The display substrate satisfies at least one of the following: an overlapping area of the scan line with the first pixel circuit within the first circuit unit is larger than an overlapping area of the scan line with the dummy pixel circuit within the second circuit unit; an overlapping area of the scan line with the first data line within the first circuit unit is larger than an overlapping area of the scan line with the dummy data line in the second circuit unit. The light emitting structure layer is located on a side of the drive circuit layer away from the base substrate, includes a plurality of first light emitting elements located in the first display region, and at least one first pixel circuit is electrically connected to at least one first light emitting element.

In some examples, an overlapping area of the scan line with the first pixel circuit within the first circuit unit may be greater than an overlapping area of the scan line with the dummy pixel circuit within the second circuit unit. Alternatively, an overlapping area of the scan line with the first data line within the first circuit unit may be larger than an overlapping area of the scan line with the dummy data line within the second circuit unit. Alternatively, an overlapping area of the scan line with the first pixel circuit within the first circuit unit may be larger than an overlapping area of the scan line with the dummy pixel circuit within the second circuit unit; further, an overlapping area of the scan line with the first data line within the first circuit unit may be larger than an overlapping area of the scan line with the dummy data line within the second circuit unit. The present embodiment is not limited thereto.

In the display substrate according to the present embodiment, by reducing an overlapping area of the scan line with the dummy pixel circuit or the dummy data line in the second circuit unit, the load of the scan line can be reduced, thereby improving the lateral poor display occurring in the display substrate.

In some exemplary implementation modes, orthographic projections of the scan line and the dummy data line within the second circuit unit on the base substrate may not overlap. Orthographic projections of the scan line and the first data line within the first circuit unit on the base substrate may partially overlap. In some examples, in one unit column where the second circuit unit is located, a plurality of dummy data lines may be sequentially arranged in the second direction, a first fracture is provided between dummy data lines adjacent in the second direction, and a length of the scan line in the second direction may be smaller than a length of the first fracture in the second direction. In this example, by reducing an overlapping area of the dummy data line and the scan line, the load of the scan line is reduced.

In some exemplary implementation modes, each of the first pixel circuit and the dummy pixel circuit may include at least a drive transistor, a data writing transistor, and a threshold compensation transistor. Gates of the data writing transistor and the threshold compensation transistor of the first pixel circuit and the dummy pixel circuit are electrically connected to the scan line. A first electrode of the data writing transistor of the first pixel circuit is electrically connected to the first data line, and a second electrode of the data writing transistor of the first pixel circuit is electrically connected to a first electrode of the drive transistor of the first pixel circuit; a first electrode of the threshold compensation transistor of the first pixel circuit is electrically connected to a gate of the drive transistor of the first pixel circuit, and a second electrode of the threshold compensation transistor of the first pixel circuit is electrically connected to a second electrode of the drive transistor of the first pixel circuit. A first electrode of the data writing transistor of the dummy pixel circuit is electrically connected to the dummy data line, and a second electrode of the data writing transistor of the dummy pixel circuit is electrically connected to a first electrode of the drive transistor of the dummy pixel circuit; a first electrode of the threshold compensation transistor of the dummy pixel circuit is electrically connected to a gate of the drive transistor of the dummy pixel circuit, and a second electrode of the threshold compensation transistor of the dummy pixel circuit is electrically connected to a second electrode of the drive transistor of the dummy pixel circuit. The display substrate may satisfy at least one of the following: the threshold compensation transistor of the first pixel circuit has a dual-gate structure, and the threshold compensation transistor of the dummy pixel circuit has a single-gate structure; a length of a gate of the data writing transistor of the first pixel circuit along the second direction is greater than a length of a gate of the data writing transistor of the dummy pixel circuit along the second direction. In this example, by reducing a size of a gate of at least one of the threshold compensation transistor and the data writing transistor of the dummy pixel circuit, an overlapping area of the scan line and the dummy pixel circuit can be reduced, thereby reducing the load of the scan line and reducing the parasitic capacitance of the scan line.

In some exemplary implementation modes, the first pixel circuit and the dummy pixel circuit may each include: a drive transistor, a first reset transistor, a threshold compensation transistor, and a storage capacitor. A gate of the drive transistor, a second electrode of the first reset transistor, a first electrode of the threshold compensation transistor and a first plate of the storage capacitor of the first pixel circuit are electrically connected with a second connection electrode. An orthographic projection of the second connection electrode on the base substrate is partially overlapped with an orthographic projection of the scan line on the base substrate. A gate of the drive transistor and a first plate of the storage capacitor of the dummy pixel circuit are electrically connected to a ninth connection electrode, a second electrode of the first reset transistor and a first electrode of the threshold compensation transistor of the dummy pixel circuit are electrically connected to a tenth connection electrode, and the ninth connection electrode and the tenth connection electrode are located at two sides of the scan line and orthographic projections of the ninth connection electrode and the tenth connection electrode on the base substrate do not overlap with the orthographic projection of the scan line on the base substrate. In this example, a connection electrode connected to a first node of the dummy pixel circuit (that is, a connection node of a gate of the drive transistor, a second electrode of the first reset transistor, a first electrode of the threshold compensation transistor, and a first plate of the storage capacitor) is disconnected at the scan line without overlapping the scan line, thereby reducing an overlapping area of the dummy pixel circuit and the scan line and reducing the load of the scan line.

In some exemplary implementation modes, the first pixel circuit may further include: a first shielding electrode located at a side of the second connection electrode away from the base substrate, an orthographic projection of the first shielding electrode on the base substrate covers an orthographic projection of the second connection electrode on the base substrate. The dummy pixel circuit further includes: a third shielding electrode and a fourth shielding electrode located at a side of the ninth connection electrode and the tenth connection electrode away from the base substrate; an orthographic projection of the third shielding electrode on the base substrate covers an orthographic projection of the ninth connection electrode on the base substrate, an orthographic projection of the fourth shielding electrode on the base substrate covers an orthographic projection of the tenth connection electrode on the base substrate, and orthographic projections of the third shielding electrode and the fourth shielding electrode on the base substrate do not overlap with the orthographic projection of the scan line on the base substrate. In this example, the shielding electrodes serving as a shield to the first node of the dummy pixel circuit (that is, the connection node of the gate of the drive transistor, a second electrode of the first reset transistor, a first electrode of the threshold compensation transistor, and the first plate of the storage capacitor) are disconnected at the scan line without overlapping the scan line, thereby further reducing the overlapping area of the dummy pixel circuit and the scan line and reducing the load of the scan line.

Solutions of the embodiments will be described below through some examples.

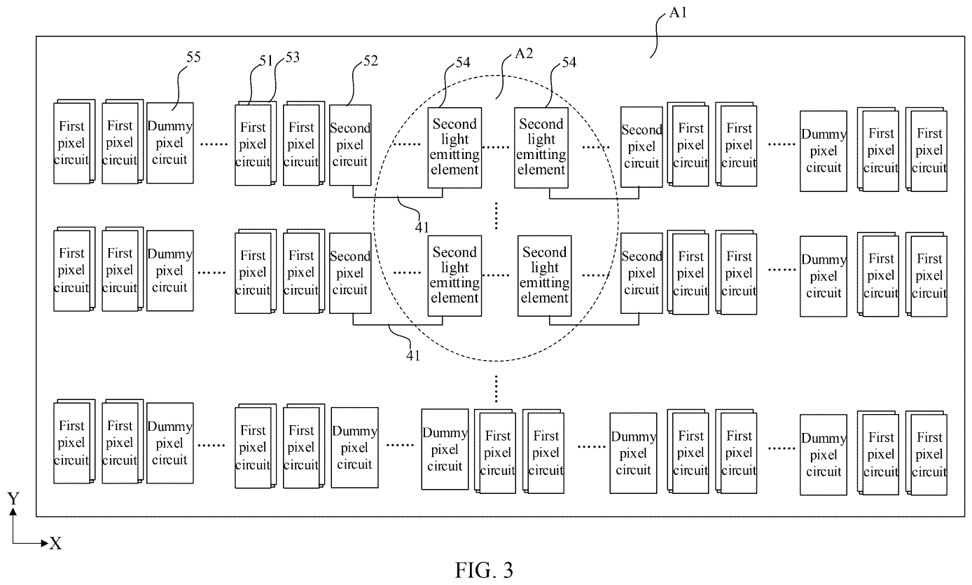

FIG. 3 is a schematic diagram of a partial structure of a display substrate according to at least one embodiment of the present disclosure. In some examples, as shown in FIG. 3, the display substrate may include at least a plurality of pixel circuits and a plurality of first light emitting elements 53 located in a first display region A1, and a plurality of second light emitting elements 54 located in a second display region A2. The plurality of pixel circuits of the first display region A1 may include a plurality of first pixel circuits 51, a plurality of second pixel circuits 52, and a plurality of dummy pixel circuits 55.

In some examples, as shown in FIG. 2, at least one first pixel circuit 51 of the plurality of first pixel circuits 51 may be electrically connected to at least one first light emitting element 53 of the plurality of first light emitting elements 53, and an orthographic projection of the at least one first pixel circuit 51 on the base substrate and an orthographic projection of the at least one first light emitting element 53 on the base substrate may at least partially overlap. The first pixel circuit 51 may be configured to provide a drive signal to the first light emitting element 53 with which the first pixel circuit 10 is connected, to drive the corresponding first light emitting element 53 to emit light. For example, the plurality of first pixel circuits 51 and the plurality of first light emitting elements 53 may be in a one-to-one relationship, or may be in a one-to-many relationship.

In some examples, as shown in FIG. 3, at least one second pixel circuit 52 of the plurality of second pixel circuits 52 may be electrically connected to at least one second light emitting element 54 of the plurality of second light emitting elements 54 through a conductive connection line 41. The second pixel circuit 52 may be configured to provide a drive signal to a second light emitting element 54 with which the second pixel circuit 12 is electrically connected to drive the corresponding second light emitting element 54 to emit light. For example, the plurality of second pixel circuits 52 and the plurality of second light emitting elements 54 may be in a one-to-one relationship or may be in a one-to-many relationship. Since a second light emitting element 54 and a second pixel circuit 52 are located in different regions, there may be no overlapping portion between an orthographic projection of at least one second pixel circuit 52 on the base substrate and an orthographic projection of at least one second light emitting element 54 on the base substrate.

In some examples, a light emitting area of a single second light emitting element 54 may be smaller than a light emitting area of a single first light emitting element 53. That is, the light emitting area of the first light emitting element 53 may be larger than that of the second light emitting element 54. A light emitting area of a single light emitting element may correspond to an area of a pixel opening of a pixel definition layer. In some examples, in the second display region A2, a transmissive region may be provided between adjacent second light emitting elements 54. For example, multiple transmissive regions may be connected with each other to form a continuous transmissive region separated by multiple second light emitting elements 54. The conductive connection line 41 is made of a transparent conductive material so as to increase the light transmittance of the transmissive region as much as possible.

In some examples, as shown in FIG. 3, the plurality of second pixel circuits 52 may be arranged at intervals between the plurality of first pixel circuits 51, and the plurality of dummy pixel circuits 55 may be arranged at intervals between the plurality of first pixel circuits 51. For example, a plurality of first pixel circuits 51 may be arranged between two second pixel circuits 52 adjacent in the first direction X, and a plurality of first pixel circuits 51 may be arranged between two adjacent dummy pixel circuits 55. In this example, by providing dummy pixel circuits 55, it is advantageous to improve the uniformity of components of a plurality of film layers in an etching process. For example, a structure of a dummy pixel circuit 55 may be substantially the same as the structure of a second pixel circuit 52 of a row or column in which the dummy pixel circuit is located, except that it is not electrically connected to any light emitting element.

In some examples, because the first display region A1 is provided with not only a first pixel circuit 51 electrically connected with a first light emitting element 53, but also a second pixel circuit 52 electrically connected with a second light emitting element 54, a quantity of pixel circuits of the first display region A1 is greater than a quantity of first light emitting elements 53. In some examples, a region where newly added pixel circuits (including a second pixel circuit 52 and a dummy pixel circuit 55) are disposed may be obtained by reducing a dimension of a first pixel circuit 51 in the first direction X. For example, a size of a pixel circuit in the first direction X may be smaller than a size of a first light emitting element in the first direction X.

In some examples, original pixel circuits of every a columns may be compressed along the first direction X, thereby obtaining an arrangement space for one newly added column of pixel circuits, and space occupied by the a columns of pixel circuits before compression may be the same as space occupied by the a+1 columns of pixel circuits after compression. Herein, a may be an integer greater than 1. In this example, a may be equal to 2. However, the present embodiment is not limited thereto. For example, a may be 3 or 4, etc.

In some examples, a second pixel circuit 52 and a dummy pixel circuit 55 may be provided in the first display region A1 at two sides (e.g., left and right sides) of the second display region A2 along the first direction X, and a second pixel circuit and a dummy pixel circuit may not be provided in the first display region A at two sides (e.g., upper and lower sides) of the second display region A2 along the second direction Y, or only a dummy pixel circuit may be provided. The present embodiment is not limited thereto.

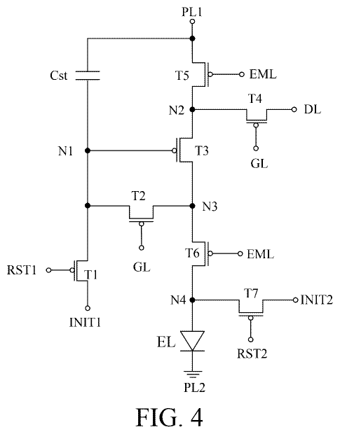

FIG. 4 is an equivalent circuit diagram of a pixel circuit according to at least one embodiment of the present disclosure. The pixel circuit of this example is a 7T1C structure. In some examples, as shown in FIG. 4, the pixel circuit of the present example may include a first transistor T1 to a seventh transistor T7. The pixel circuit may be electrically connected to a scan line GL, a data line DL, a first power supply line PL1, a second power supply line PL2, a light emitting control line EML, a first initial signal line INIT1, a second initial signal line INIT2, a first reset control line RST1 and a second reset control line RST2. A light emitting element EL may include an anode, a cathode, and an organic light emitting layer provided between the anode and the cathode.

In some examples, as shown in FIG. 4, the first power supply line PL1 may be configured to provide a constant first voltage signal VDD to the pixel circuit, the second power supply line PL2 may be configured to provide a constant second voltage signal VSS to the pixel circuit, and the first voltage signal VDD is greater than the second voltage signal VSS. The scan line GL may be configured to provide a scan signal SCAN to the pixel circuit, the data line DL may be configured to provide a data signal to the pixel circuit, the light emitting control line EML may be configured to provide a light emitting control signal EM to the pixel circuit, the first reset control line RST1 may be configured to provide a first reset control signal RESET1 to the pixel circuit, and the second reset control line RST2 may be configured to provide a second reset signal RESET2 to the pixel circuit.

In some examples, in a row of pixel circuits, a second reset control line RST2 may be connected with a scan line GL to be input with a scan signal SCAN. That is, a second reset signal RESET2(n) received by a pixel circuit of an n-th row is a scan signal SCAN(n) received by the pixel circuit of the n-th row. However, the present embodiment is not limited thereto. For example, the second reset control signal line RST2 may be input with a second reset control signal RESET2 different from the scan signal SCAN. In some examples, in a pixel circuit of an n-th row, a first reset control line RST1 may be connected with a scan line GL of a pixel circuit of an (n−1)-th row to be input with a scan signal SCAN(n−1), that is, a first reset control signal RESET1(n) is the same as the scan signal SCAN(n−1). Thus, signal lines of the display substrate may be reduced, and a narrow bezel of the display substrate may be achieved.

In some examples, as shown in FIG. 4, a gate of the third transistor T3 is electrically connected with a first node N1, a first electrode of the third transistor T3 is electrically connected with a second node N2, and a second electrode of the third transistor T3 is electrically connected with a third node N3. The third transistor T3 may be referred to as a drive transistor. A gate of the first transistor T1 is electrically connected with a first reset control line RST1, a first electrode of the first transistor T1 is electrically connected with a first initial signal line INIT1, and a second electrode of the first transistor T1 is electrically connected with the gate of the third transistor T3. The first transistor T1 may also be referred to as a first reset transistor and is configured to reset the gate of the third transistor T3. A gate of the second transistor T2 is electrically connected with the scan line GL, a first electrode of the second transistor T2 is electrically connected with the gate of the third transistor T3, and a second electrode of the second transistor T2 is electrically connected with a second electrode of the third transistor T3. The second transistor T2 may also be referred to as a threshold compensation transistor. A gate of the fourth transistor T4 is electrically connected with the scan line GL, a first electrode of the fourth transistor T4 is electrically connected with the data line DL, and a second electrode of the fourth transistor T4 is electrically connected with a first electrode of the third transistor T3. The fourth transistor T4 may be referred to as a data writing transistor. A gate electrode of the fifth transistor T5 is electrically connected with the light emitting control line EML, a first electrode of the fifth transistor T5 is electrically connected with the first power supply line PL1, and a second electrode of the fifth transistor T5 is electrically connected with a first electrode of the third transistor T3. The fifth transistor T5 may also be referred to as a first light emitting control transistor. A gate of the sixth transistor T6 is electrically connected with the light emitting control line EML, a first electrode of the sixth transistor T6 is electrically connected with a second electrode of the third transistor T3, and a second electrode of the sixth transistor T6 is electrically connected with an anode of the light emitting element EL. The sixth transistor T6 may also be referred to as a second light emitting control transistor. A gate electrode of the seventh transistor T7 is electrically connected with a second reset control line RST2, a first electrode of the seventh transistor T7 is electrically connected with a second initial signal line INIT2, and a second electrode of the seventh transistor T7 is electrically connected with the anode of the light emitting element EL. The seventh transistor T7 may also be referred to as a second reset transistor, and is configured to reset the anode of the light emitting element EL. A first electrode of a storage capacitor Cst is electrically connected with the gate of the third transistor T3, and a second electrode of the storage capacitor Cst is electrically connected with the first power supply line PL1. A cathode of the light emitting element EL is electrically connected with the second power supply line PL2.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, and the fourth node N4 is a connection point for the sixth transistor T6, the seventh transistor T7, and the light emitting element EL.

An operating process of the pixel drive circuit shown in FIG. 4 will be described below. The description is given by taking a case in which a plurality of transistors included in the pixel circuit shown in FIG. 4 are all P-type transistors as an example.

In some examples, during one-frame display time period, the operating process of the pixel circuit may include a first stage, a second stage, and a third stage. In this example, description is given by taking a case in which the second reset control line RST2 and the scan line GL transmit a same signal as an example.

The first stage is referred to as a reset stage. A first reset control signal RESET1 provided by the first reset control line RST1 is a low-level signal, so that the first transistor T1 is turned on, and a first initial signal provided by the first initial signal line INIT1 is provided to the first node N1 to initialize the first node N1 and clear an original data voltage in the storage capacitor Cst. A scan signal SCAN provided by the scan line GL is a high-level signal and the light control signal EM provided by the light emitting control line EML is a high-level signal, so that the fourth transistor T4, the second transistor T2, the fifth transistor T5, the sixth transistor T6, and the seventh transistor T7 are turned off. In this stage, the light emitting element EL does not emit light.

The second stage is referred to as a data writing stage or a threshold compensation stage. A scan signal SCAN provided by the scan line GL is a low-level signal, a first reset control signal RESET1 provided by the first reset control line RST1 and an emitting control signal EM provided by the emitting control line EML are both high-level signals, and the data line DL outputs a data signal. In this phase, a first electrode of the storage capacitor Cst is at a low level, such that the drive transistor T3 is turned on. The scan signal SCAN is a low-level signal, so that the second transistor T2, the fourth transistor T4, and the seventh transistor T7 are turned on. The second transistor T2 and the fourth transistor T4 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of a first electrode (i.e., the first node N1) of the storage capacitor Cst is Vdata-|Vth|, wherein Vdata is the data voltage output by the data line DL, and Vth is the threshold voltage of the third transistor T3. The seventh transistor T7 is turned on, so that a second initial signal (i.e., an anode reset signal) provided by the second initial signal line INIT2 is provided to the anode of the light emitting element EL to initialize (reset) the anode of the light emitting element EL and clear a pre-stored voltage therein, so as to complete initialization, thereby ensuring that the light emitting element EL does not emit light. The first reset control signal RESET1 provided by the first reset control line RST1 is a high-level signal, so that the first transistor T1 is turned off. The light emitting control signal EM provided by the light emitting control line EML is a high-level signal, so that the fifth transistor T5 and the sixth transistor T6 are turned off.

The third stage is referred to as a light emitting stage. A light emitting control signal EM provided by the light emitting signal line EML is a low-level signal, and a scan signal SCAN provided by the scan line GL and a first reset control signal RESET1 provided by the first reset control line RST1 are high-level signals. The light emitting control signal EM provided by the light emitting control line EML is a low-level signal, so that the fifth transistor T5 and the sixth transistor T6 are turned on, and the first voltage signal VDD output from the first power supply line PL1 provides a drive voltage to the anode of the light emitting device EL through the turned-on fifth transistor T5, third transistor T3 and sixth transistor T6 to drive the light emitting element EL to emit light.

In a driving process of the pixel circuit, a drive current flowing through the third transistor T3 is determined by a voltage difference between the gate and a first electrode of the third transistor T3. Since a voltage of the first node N1 is Vdata-|Vth|, the drive current of the third transistor T3 is as follows.

I=K×(Vgs−Vth)²=K×[(VDD−Vdata+|Vth|)−Vth]²=K×[VDD−Vdata]².

herein, I is the drive current flowing through the third transistor T3, that is, a drive current for driving the light emitting device EL, K is a constant, Vgs is the voltage difference between the gate and a first electrode of the third transistor T3, Vth is the threshold voltage of the third transistor T3, Vdata is the data voltage outputted by the data signal line DL, and VDD is the first voltage signal outputted by the first power supply line PL1.

It may be seen from the above formula that a current flowing through the light emitting element EL is independent of the threshold voltage of the third transistor T3. Therefore, the pixel circuit according to this embodiment may better compensate the threshold voltage of the third transistor T3.

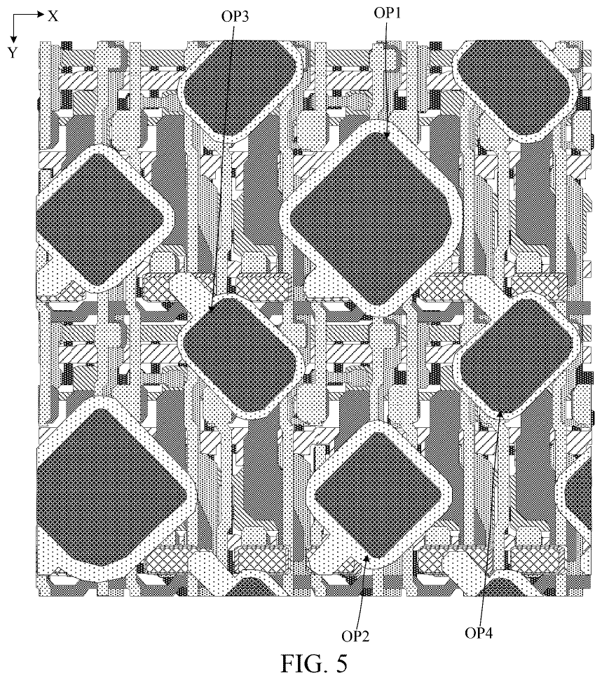

FIG. 5 is a schematic partial plan view of a first display region according to at least one embodiment of the present disclosure. In the present example, a plurality of circuit units sequentially arranged in the first direction X may be referred to as one unit row, and a plurality of circuit units sequentially arranged in the second direction Y may be referred to as one unit column.

In some examples, as shown in FIG. 5, the first display region may include at least a base substrate, and a drive circuit layer, a conductive connection layer, and a light emitting structure layer disposed on the base substrate sequentially. The drive circuit layer may include at least a plurality of first pixel circuits, a plurality of second pixel circuits, and a plurality of dummy pixel circuits. The circuit structures of a first pixel circuit, a second pixel circuit, and a dummy pixel circuit may all be a 7T1C structure as shown in FIG. 4. The conductive connection layer may include at least a plurality of conductive connection lines, and a conductive connection line may be configured to extend to the second display region to electrically connect a corresponding second pixel circuit with a second light emitting element located in the second display region. The light emitting structure layer may include at least a plurality of first light emitting elements located in the first display region and a plurality of second light emitting elements located in the second display region, and the plurality of first light emitting elements may be electrically connected to the plurality of first pixel circuits.

Hereinafter, with reference to FIGS. 5 to 22B, the structure of the first display region of the display substrate of the present example will be described through a preparation process of the display substrate.

A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

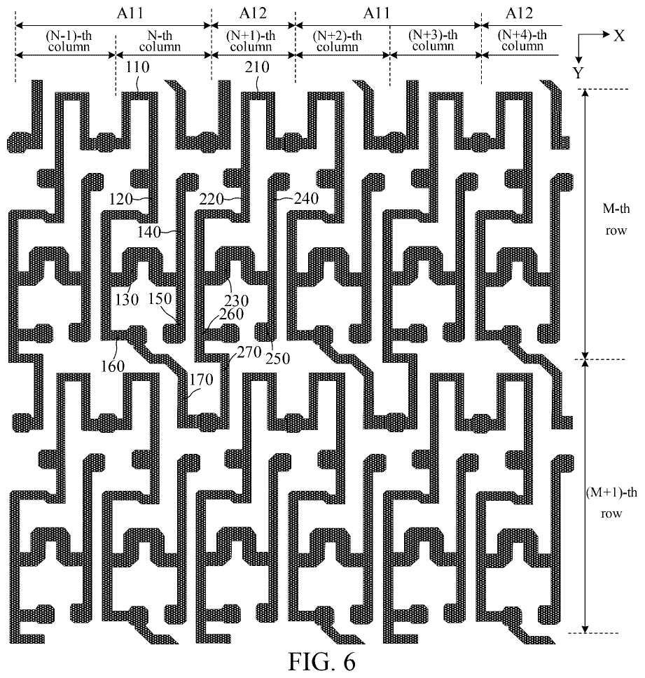

In some examples, as shown in FIGS. 6 to 21, the first display region may include first circuit regions A11 and second circuit regions A12 arranged at intervals along the first direction X. A first circuit region A11 may be provided with a plurality of unit columns (for example, two unit columns), and a second circuit region A12 may be provided with one unit column. The plurality of unit columns of the first circuit region A11 may include a plurality of first circuit units, and each of the first circuit units may include at least a first pixel circuit and a scan line and a first data line electrically connected to the first pixel circuit. A first pixel circuit may include a first transistor 11 to a seventh transistor 17 and a storage capacitor 18. One unit column of the second circuit region A12 may include a plurality of second circuit units, and at least one of the second circuit units may include a dummy pixel circuit and a scan line and a dummy data line electrically connected to the dummy pixel circuit. The dummy pixel circuit may include a first transistor 21 to a seventh transistor 27 and a storage capacitor 28.

In this example, it is illustrated by taking circuit units arranged in two rows and six columns (including, for example, an (N−1)-th column to an (N+4)-th column, and an M-th row and an (M+1)-th row) as an example. The (N−1)-th column, the (N+2)-th column, and the (N+3)-th column of circuit units include: a plurality of first circuit units; the (N+1)-th column and the (N+4)-th column of circuit units include a plurality of second circuit units. Description is given below by taking the structures of the first circuit unit in the N-th column and the M-th row and a second circuit unit in the (N+1)-th column and the M-th row as an example.

In some examples, the preparing process of the display substrate may include the following operations.

(1) A base substrate is provided. In some examples, the base substrate may be a rigid substrate or a flexible substrate. For example, the rigid substrate may be made of, but not limited to, one or more of glass and quartz. The flexible substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base substrate may include a first flexible material layer, a first inorganic material layer, a second flexible material layer and a second inorganic material layer which are stacked. The first flexible material layer and the second flexible material layer may be made of a material such as Polyimide (PI), Polyethylene Terephthalate (PET), or a polymer soft film on which surface treatment is performed, and a material of the first inorganic material layer and the second inorganic material layer may be Silicon Nitride (SiNx, x>0) or Silicon Oxide (SiOy,y>0), etc., which are used to improve resistance to water and oxygen of the base substrate.

(2) A semiconductor layer is formed. In some examples, a semiconductor thin film is deposited on the base substrate, and the semiconductor thin film is patterned through a patterning process to form a semiconductor layer disposed on the base substrate.

In some examples, an active layer of each transistor may include: a first region, a second region, and a channel region located between the first region and the second region. A material of the semiconductor layer may include polysilicon, for example. The channel region may be not doped with impurities, and has characteristics of a semiconductor. The first region and the second region may be doped regions on both sides of the channel region, and are doped with impurities, and thus have conductivity. The impurities may be different according to a type of a transistor. In some examples, a doped region of the active layer may be interpreted as a source electrode or a drain electrode of a transistor. A part of active layers between transistors may be interpreted as a wiring doped with impurities, and may be used for electrically connecting the transistors. The present embodiment is not limited thereto. In other examples, the material of the semiconductor layer may include a material, such as an amorphous indium gallium zinc oxide material (a-IGZO), zinc oxynitride (ZnON) and indium zinc tin oxide (IZTO). The present embodiment can be applicable to a transistor manufactured based on an oxide technology, a silicon technology, or an organic matter technology.

FIG. 6 is a schematic plan diagram of the display substrate after a semiconductor layer is formed in FIG. 5. In some examples, as shown in FIG. 6, the semiconductor layer of the first circuit unit may include at least: active layers of a plurality of transistors of the first pixel circuit (e.g., including a first active layer 110 of a first transistor, a second active layer 120 of a second transistor, a third active layer 130 of a third transistor, a fourth active layer 140 of a fourth transistor, a fifth active layer 150 of a fifth transistor, a sixth active layer 160 of a sixth transistor in a first pixel circuit of a present row, and a seventh active layer 170 of a seventh transistor in a first pixel circuit of a previous row). The active layers of the seven transistors of the first pixel circuit may be of an interconnected integral structure.

In some examples, as shown in FIG. 6, the semiconductor layer of the second circuit unit may include at least: active layers of a plurality of transistors of a dummy pixel circuit (e.g., including a first active layer 210 of a first transistor, a second active layer 220 of a second transistor, a third active layer 230 of a third transistor, a fourth active layer 240 of a fourth transistor, a fifth active layer 250 of a fifth transistor, a sixth active layer 260 of a sixth transistor in a dummy pixel circuit of a present row, and a seventh active layer 270 of a seventh transistor in a dummy pixel circuit of a previous row). The active layers of the seven transistors of the dummy pixel circuit may be of an interconnected integral structure.

In some examples, as shown in FIG. 6, in an unit row, the active layers of pixel circuits within a (2i−1)-th circuit unit and a 2i-th circuit unit may be of an interconnected integral structure, and i is an integer greater than 0. For example, the first active layer of the first pixel circuit in the circuit unit (i.e., the first circuit unit) in the M-th row and (N−1)-th column and the first active layer 110 of the first pixel circuit in the circuit unit (i.e., the first circuit unit) in the M-th row and the N-th column may be of an interconnected integral structure. The first active layer 210 of the dummy pixel circuit in the circuit unit (that is, the second circuit unit) in the M-th row and the (N+1)-th column and the first active layer of the first pixel circuit in the circuit unit (that is, the first circuit unit) in the M-th column and the (N+2)-th column may be of an interconnected integral structure.

In some examples, as shown in FIG. 6, in an unit row, the active layers of pixel circuits within the 2i-th circuit unit and the (2i+1)-th circuit unit may be of an interconnected integral structure, and i is an integer greater than 0. For example, the seventh active layer 170 of the first pixel unit in the circuit unit (i.e., the first circuit unit) of the M-th row and the N-th column and the seventh active layer 270 of the dummy pixel circuit in the circuit unit (i.e., the second circuit unit) in the M-th row and the (N+1)-th column may be of an interconnected integral structure.

The arrangement of the active layers of the pixel circuits in the first display region of the present example may be advantageous to realize a compact arrangement of the pixel circuits, thereby saving occupied space.

In some examples, as shown in FIG. 6, the first active layers 110 and 210 may be substantially in an “n” shape, the second active layers 120 and 220, the sixth active layers 160 and 260, the seventh active layer 270 may be substantially in an “L” shape, the third active layers 130 and 230 may be substantially in an “Q” shape, the fourth active layers 140 and 240 and the fifth active layers 150 and 250 may be substantially in an “I” shape. The seventh active layer 170 may substantially be in a shape of a bending line. The present embodiment is not limited thereto.

In some examples, a first region of the fourth active layer 140 and a first region of the fifth active layer 150 of the first pixel circuit may be separately provided. A first region of the first active layer 110 of the first pixel circuit may be connected to a first region of the first active layer of a pixel circuit adjacent along an opposite direction of the first direction X, and a second region of the first active layer 110 of the first pixel circuit may simultaneously serve as a first region of the second active layer 120. A first region of the third active layer 130 may simultaneously serve as a second region of the fourth active layer 140 and a second region of the fifth active layer 150; a second region of the third active layer 130 may simultaneously serve as a second region of the second active layer 120 and a first region of the sixth active layer 160; a second region of the sixth active layer 160 may simultaneously serve as a first region of the seventh active layer 170. A first region of the seventh active layer 170 may be connected to a first region of the seventh active layer of a pixel circuit adjacent along the first direction X. Structures of active layers of a dummy pixel circuit are similar to the structures of the active layers of the first pixel circuit, so it will not be repeated here.

(3) A first conductive layer is formed. In some examples, a first insulating thin film and a first conductive thin film are deposited sequentially on the base substrate on which the above-mentioned patterns are formed, and the first conductive thin film is patterned through a patterning process to form a first insulating layer and a first conductive layer disposed on the first insulating layer. In some examples, the first conductive layer may also be referred to as a first gate metal layer.

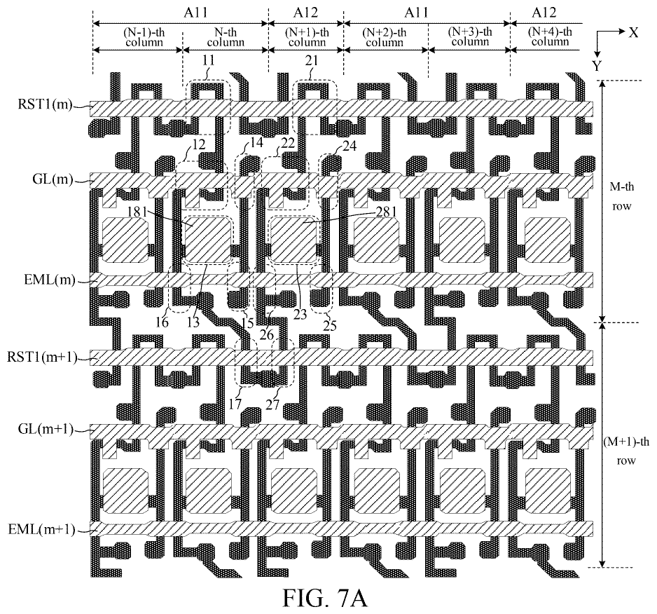

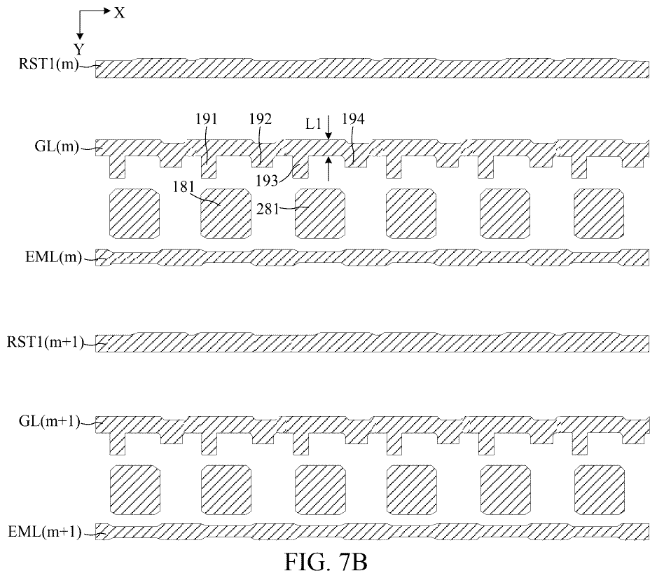

FIG. 7A is a schematic plan view of the display substrate after a first conductive layer is formed in FIG. 5. FIG. 7B is a schematic diagram of the first conductive layer in FIG. 7A. In some examples, as shown in FIGS. 7A and 7B, the first conductive layer of the first circuit unit may include at least: gates of a plurality of transistors of the first pixel circuit (for example, including gates of the first transistor 11 to the sixth transistor 16 in a first pixel circuit of a present row, and a gate of the seventh transistor of a first pixel circuit of a previous row) and a first plate 181 of the storage capacitor, a first reset control line (for example, a first reset control line RST1(m) or RST1(m+1)), a scan line (for example, a scan line GL(m) or GL(m+1)), and a light emitting control line (for example, a light emitting control line EML(m) or EML(m+1).

In some examples, as shown in FIGS. 7A and 7B, the first conductive layer of the second circuit unit may include at least: gates of a plurality of transistors of the dummy pixel circuit (for example, including gates of the first transistor 21 to the sixth transistor 26 in a dummy pixel circuit of a present row, a first plate 281 of the storage capacitor, and a gate of the seventh transistor 27 in a dummy pixel circuit of a previous row), a first reset control line (for example, a first reset control line RST1(m) or RST1(m+1)), a scan line (for example, a scan line GL(m) or GL(m+1)), and a light emitting control line (for example, a light emitting control line EML(m) or EML(m+1)).

Description is given below by taking the first reset control line RST1(m), the scan line GL(m), and the light emitting control line EML(m) as an example, and the structures of the first reset control line RST1(m+1), the scan line GL(m+1), and the light emitting control line EML(m+1) are similar, and thus the description thereof will not be repeated here.

In some examples, the scan line GL(m) is located at a side of the first reset control line RST1(m) in the second direction Y. The light emitting control line EML(m) is located at a side of the scan line GL(m) in the second direction Y. The first plates 181 of the storage capacitors of the first pixel circuits and the first plates 281 of the storage capacitors of the dummy pixel circuits in the M-th row may be arranged at intervals in the first direction X, and be located between the light emitting control line EML(m) and the scan line GL(m) in the second direction Y.

In some examples, the first reset control line RST1(m) may substantially be in a shape of a straight line extending in the first direction X. In the first circuit unit, a region where the first reset control line RST1(m) overlaps the first active layer of the first transistor 11 of the first pixel circuit of a present row may serve as a gate of the first transistor 11 having a dual-gate structure, and a region where the first reset control line RST1(m) overlaps the seventh active layer of the seventh transistor of the first pixel circuit of a previous row may serve as a gate of the seventh transistor. In the second circuit unit, a region where the first reset control line RST1(m) overlaps the first active layer of the first transistor 21 of the dummy pixel circuit of a present row may serve as a gate of the first transistor 21 having a dual-gate structure, and a region where the first reset control line RST1(m) overlaps the seventh active layer of the seventh transistor of the dummy pixel circuit of a previous row may serve as a gate of the seventh transistor.

In some examples, the scan line GL(m) may be substantially in a shape of a straight line with a main body portion extending in the first direction X. A length of the scan line GL(m) in the second direction Y may be denoted as L1. In the first circuit unit, a region where the scan line GL(m) overlaps the second active layer of the second transistor 12 of the first pixel circuit of a present row may serve as a first gate of the second transistor 12 having a dual-gate structure, and a region where the scan line GL(m) overlaps the fourth active layer of the fourth transistor 14 of the first pixel circuit of a present row may serve as a gate of the fourth transistor 14. In the second circuit unit, a region in which the scan line GL(m) overlaps the second active layer of the second transistor 22 of the dummy pixel circuit of a present row may serve as a first gate of the second transistor 22 having a dual-gate structure, and a region in which the scan line GL(m) overlaps the fourth active layer of the fourth transistor 24 of the dummy pixel circuit of a present row may serve as a gate of the fourth transistor 24.

In some examples, in the first circuit unit, a first protrusion 191 may be provided on a side of the scan line GL(m) away from the first reset control line RST1(m). The first protrusion 191 may be substantially in a shape of a rectangle. A first end of the first protrusion 191 is connected to the scan line GL(m), and a second end of the first protrusion 191 extends in the direction of the first plate 181 of the storage capacitor. A region where the first protrusion 191 overlaps the second active layer of the second transistor 12 of the first pixel circuit of a present row may serve as a second gate of the second transistor 12 having a dual-gate structure. The scan line GL(m) and the first protrusions 191 may be of an interconnected integral structure.

In some examples, in the first circuit unit, a second protrusions 192 may be provided on a side of the scan line GL(m) away from the first reset control line RST1(m). The second protrusion 192 may be substantially in a shape of a rectangle. A first end of the second protrusion 192 is connected to the scan line GL(m), and a second end of the second protrusion 192 extends in the direction of the first plate 181 of the storage capacitor. A region where the second protrusion 192 overlaps the fourth active layer of the fourth transistor 14 of the first pixel circuit of a present row may serve as a gate of the fourth transistor 14. The second protrusions 192 and the first protrusion 191 may be provided at intervals along the first direction X. The length of the first protrusion 191 in the second direction Y may be longer than the length of the second protrusion 192 in the second direction Y. The length of the first protrusion 191 in the first direction X may be smaller than the length of the second protrusion 192 in the first direction X. The scan line GL(m) and the second protrusion 192 may be of an interconnected integral structure. In this example, by providing the second protrusion 192, the size of the gate of the fourth transistor 14 in the second direction Y can be increased, and the size of the channel region of the fourth transistor 14 can be increased, thereby ensuring the data writing performance of the first pixel circuit.

In some examples, in the second circuit unit, a third protrusion 193 may be provided on a side of the scan line GL(m) away from the first reset control line RST1(m). The third protrusion 193 may be substantially in a shape of a rectangle. A first end of the third protrusion 193 is connected to the scan line GL(m), and a second end of the third protrusion 193 extends in the direction of the first plate 281 of the storage capacitor. A region where the third protrusion 193 overlaps the second active layer of the second transistor 22 of the dummy pixel circuit of a present row may serve as a second gate of the second transistor 22 having a dual-gate structure. The scan line GL(m) and the third protrusion 193 may be of an interconnected integral structure. The shape and size of the third protruding portion 193 and the shape and size of the first protruding portion 191 may be substantially the same.

In some examples, in the second circuit unit, a fourth protrusion 194 may be provided on a side of the scan line GL(m) away from the first reset control line RST1(m). The fourth protrusion 194 may be substantially in a shape of a rectangle. A first end of the fourth protrusion 194 is connected to the scan line GL(m), and a second end of the fourth protrusion 194 extends in the direction of the first plate 281 of the storage capacitor. A region where the fourth protrusion 194 overlaps the fourth active layer of the fourth transistor 24 of the dummy pixel circuit of a present row may serve as a gate of the fourth transistor 24. The fourth protrusion 194 and the third protrusion 193 may be provided at intervals along the first direction X. The length of the third protrusion 193 in the second direction Y may be longer than the length of the fourth protrusion 194 in the second direction Y. The length of the third protrusion 193 in the first direction X may be smaller than the length of the fourth protrusion 194 in the first direction X. The shape and size of the fourth protrusion 194 and the shape and size of the second protrusion 192 may be substantially the same. The scan line GL(m) and the fourth protrusion 194 may be of an interconnected integral structure.

In some examples, within the first circuit unit, the first plate 181 of the storage capacitor of the first pixel circuit may be substantially in a shape of a rectangle, and corners of the rectangle may be provided with chamfers. An orthographic projection of the first plate 181 on the base substrate and an orthographic projection of the third active layer of the third transistor 13 on the base substrate may at least partially overlap, and the first plate 181 may simultaneously serve as a first electrode (i.e., a lower plate) of the storage capacitor and a gate of the third transistor 13 in the first pixel circuit.

In some examples, within the second circuit unit, the first plate 281 of the storage capacitor of the dummy pixel circuit may be substantially in a shape of a rectangle, and corners of the rectangle may be provided with chamfers. An orthographic projection of the first plate 281 on the base substrate and an orthographic projection of the third active layer of the third transistor 23 on the base substrate may at least partially overlap, and the first plate 281 may simultaneously serve as a first electrode (i.e., a lower plate) of the storage capacitor of the dummy pixel circuit and a gate of the third transistor 23.

In some examples, the light emitting control line EML(m) may substantially be in a shape of a straight line extending along the first direction X. In the first circuit unit, a region where the light emitting control line EML(m) overlaps the fifth active layer of the fifth transistor 15 of the first pixel circuit of a present row may serve as a gate of the fifth transistor 15, and a region where the light emitting control line EML(m) overlaps the sixth active layer of the sixth transistor 16 of the first pixel circuit of a present row may serve as a gate of the sixth transistor 16. In the second circuit unit, a region where the light emitting control line EML(m) overlaps the fifth active layer of the fifth transistor 25 of the dummy pixel circuit of a present row may serve as a gate of the fifth transistor 25, and a region where the light emitting control line EML(m) overlaps the sixth active layer of the sixth transistor 26 of the dummy pixel circuit of a present row may serve as a gate of the sixth transistor 26.

In some examples, after the pattern of the first conductive layer is formed, the semiconductor layer may be subjected to a conductorization treatment by using the first conductive layer as a shield, A region of the semiconductor layer, which is shielded by the first conductive layer, may form channel regions of the seven transistors of the first pixel circuit and the seven transistors of the dummy pixel circuit, and a region of the semiconductor layer, which is not shielded by the first conductive layer, is made to be conductorized, that is, the first and second regions of the seven transistors of the first pixel circuit and the first and second regions of the seven transistors of the dummy pixel circuit may be all made to be conductorized.

(4) A second conductive layer is formed. In some examples, a second insulating thin film and a second conductive thin film are sequentially deposited on the base substrate on which the above-mentioned patterns are formed, and the second conductive thin film is patterned through a patterning process to form a second insulating layer and a second conductive layer disposed on the second insulating layer. In some examples, the second conductive layer may also be referred to as a second gate metal layer.

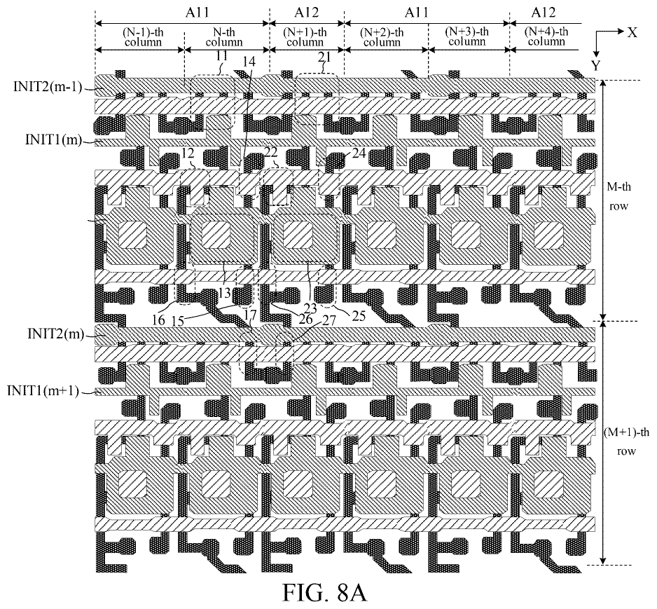

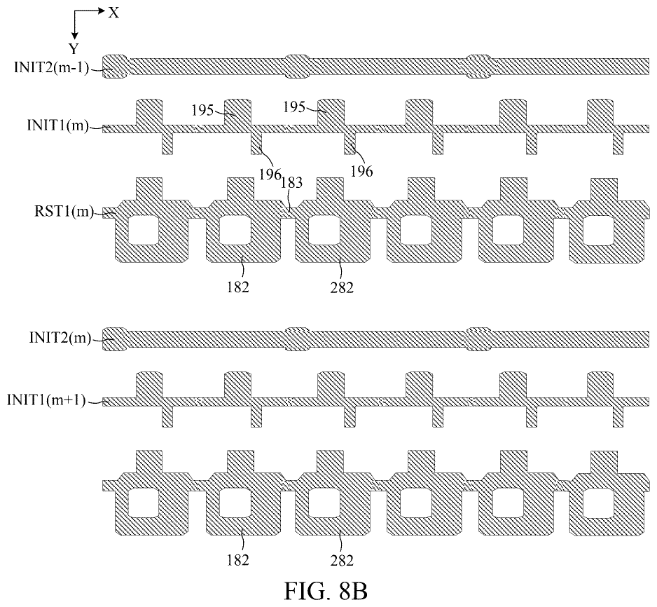

FIG. 8A is a schematic plan view of the display substrate after a second conductive layer is formed in FIG. 5. FIG. 8B is a schematic diagram of the second conductive layer in FIG. 8A. In some examples, as shown in FIGS. 8A and 8B, the second conductive layer of the first circuit unit may include at least a second plate 182 of the storage capacitor of the first pixel circuit, a first initial signal line (e.g., a first initial signal line INIT1(m) or INIT1(m+1)), a second initial signal line (e.g., a second initial signal line INIT2(m−1) or INIT2(m)). The second conductive layer of the second circuit unit may include at least a second plate 282 of the storage capacitor of the dummy pixel circuit, the first initial signal line (for example, the first initial signal line INIT1(m) or INIT1(m+1)), the second initial signal line (for example, the second initial signal line INIT2(m−1) or INIT2(m)).

Description is given below by taking the first initial signal line INIT1(m) and the second initial signal line INIT2(m−1) as an example, and the structures of the first initial signal line INIT1(m+1) and the second initial signal line INIT2(m) are similar, and thus the description thereof will not be repeated here.

In some examples, an orthographic projection of the second initial signal line INIT2(m−1) on the base substrate is located at a side of the first reset control line RST1(m) in an opposite direction of the second direction Y. The first initial signal line INIT1(m) may be located at a side of the second initial signal line INIT2(m-1) in the second direction Y. The second plate 182 of the storage capacitor of the first pixel circuit and the second plate 282 of the storage capacitor of the dummy pixel circuit in the M-th row may be arranged at intervals in the first direction X and located at a side of the first initial signal line INIT1(m) in the second direction Y.

In some examples, the second initial signal line INIT2(m−1) and the first initial signal line INIT1(m) may be substantially in a shape of a straight line with a main body portion extending in the first direction X. The length of the main body portion of the second initial signal line INIT2(m−1) in the second direction Y may be larger than the length of the main body portion of the first initial signal line INIT1(m) in the second direction Y.

In some examples, in the first circuit unit and the second circuit unit, a fifth protrusion 195 may be provided on a side of the first initial signal line INIT1(m) close to the second initial signal line INIT2(m−1), and the fifth protrusion 195 may be substantially in a shape of a rectangle. A first end of the fifth protrusion 195 is connected to the first initial signal line INIT1(m), and a second end of the fifth protrusion 195 extends in the direction of the second initial signal line INIT2(m−1). For example, the fifth protrusion 195 may be located between a first region of a first active layer and a first region of an adjacent seventh active layer. The fifth protrusion 195 and the first initial signal line INIT1(m) may be of an interconnected integral structure.

In some examples, in the first circuit unit and the second circuit unit, a sixth protrusion 196 may be provided on a side of the first initial signal line INIT1(m) away from the second initial signal line INIT2(m−1), and the sixth protrusion 196 may be substantially in a shape of a rectangle. The sixth protrusion 196 and the fifth protrusion 195 may be disposed at intervals along the first direction X. The length of the sixth protrusion 196 in the first direction X may be smaller than the length of the fifth protrusion 195 in the first direction X. A first end of the sixth projection 196 is connected to the first initial signal line INIT1(m), and a second end of the sixth projection 196 extends in the direction of the second plate 182 or 282 of the storage capacitor. For example, the sixth protrusion 196 may be located between a first region of the second active layer and a first region of the fourth active layer in the first pixel circuit (or the dummy pixel circuit). The sixth protrusion 196 and the first initial signal line INIT1(m) may be of an interconnected integral structure. The present example helps shield the fourth transistor from other signals by providing the sixth protrusion 196.

In some examples, within the first circuit unit, orthographic projections of the second plate 182 and the first plate 181 of the storage capacitor of the first pixel circuit on the base substrate may partially overlap. The second plate 182 may have a first opening, the first opening may be substantially in a shape of a rectangle, and an orthographic projection of the first opening on the base substrate may be located within a range of an orthographic projection of the first plate 181 on the base substrate. The first plate of the storage capacitor of the first pixel circuit may serve as a first electrode of the storage capacitor, and the second plate of the storage capacitor may serve as a second electrode of the storage capacitor.

In some examples, within the second circuit unit, orthographic projections of the second plate 282 and the first plate 281 of the storage capacitor of the dummy pixel circuit on the base substrate may partially overlap. The second plate 282 may have a second opening, the second opening may be substantially in a shape of a rectangle, and an orthographic projection of the second opening on the base substrate may be located within a range of an orthographic projection of the first plate 281 on the base substrate. The first plate of the storage capacitor of the dummy pixel circuit may serve as a first electrode of the storage capacitor, and the second plate of the storage capacitor may serve as a second electrode of the storage capacitor.

In some examples, a plate connection line 183 may be provided on a side of the second plate 282 (or 182) in the first direction X or in an opposite side of the first direction X. A first end of the plate connection line 183 may be connected to the second plate of the present circuit unit, and the second end of the plate connection line, after extending along the first direction X or the opposite direction of the first direction X, may be connected to the second plate of an adjacent circuit unit, so that second plates of adjacent circuit units in one unit row may be connected to each other. For example, the second plate 182 of the first pixel circuit in the first circuit unit may be connected to the second plate 282 of the dummy pixel circuit through the plate connection line 183. In some examples, the plate connection line 183 and the second plates 182 and 282 may be of an interconnected integral structure. The second plates (including the second plates 182 and 282) of the integral structure of the plurality of circuit units of the present example can be reused as a transverse trace extending along the first direction X for transmitting a first voltage signal, which can not only ensure that a plurality of second plates in one unit row have the same potential, but also reduce the voltage drop of the first voltage signal, which is beneficial to improving the uniformity of the display substrate and ensuring the display effect.

(5) A third insulating layer is formed. In some examples, a third insulating thin film is deposited on the base substrate on which the aforementioned patterns are formed, and the third insulating thin film is patterned through a patterning process to form a third insulating layer. A plurality of vias are provided in the third insulating layer of each circuit unit. In some examples, the third insulating layer may also be referred to as an interlayer dielectric layer.

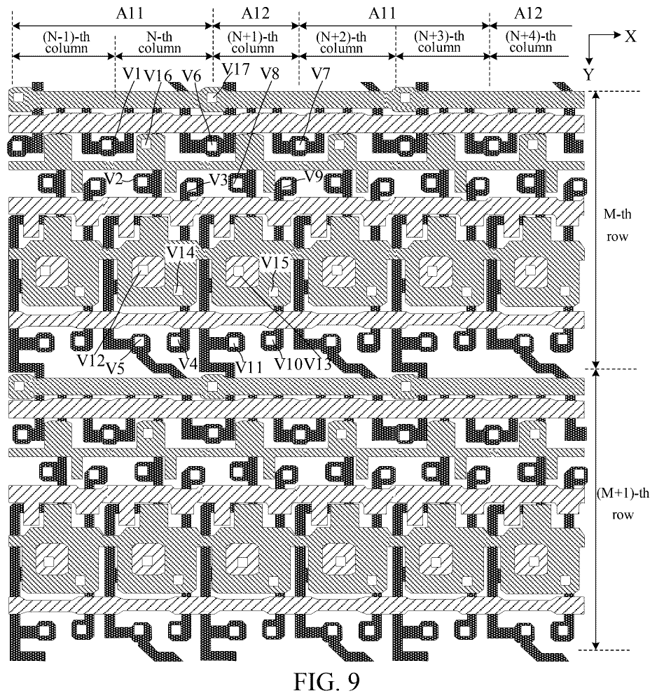

FIG. 9 is a schematic plan view of a display substrate after a third insulating layer is formed in FIG. 5. In some examples, as shown in FIG. 9, the plurality of vias of the first circuit unit may include at least a first via V1, a second via V2, a third via V3, a fourth via V4, a fifth via V5, a sixth via V6, a twelfth via V12, a fourteenth via V14, and a sixteenth via V16. The plurality of vias of the second circuit unit may include at least a seventh via V7, an eighth via V8, a ninth via V9, a tenth via V10, an eleventh via V11, a thirteenth via V13, a fifteenth via V15, and a seventeenth via V17. For example, the first via V1 may be located at a junction of the (N−1)-th column of circuit units and the N-th column of circuit units, the seventeenth via V17 may be located at a junction of the N-th column of circuit units and the (N+1)-th column of circuit units, and the seventh via V7 may be located at a junction of the (N+1)-th column of circuit units and the (N+2)-th column of circuit units.

In some examples, the fifth insulating layer, the fourth insulating layer, the third insulating layer, the second insulating layer, and the first insulating layer within the first via V1 to the eleventh via V11 may be removed to expose a portion of a surface of the first semiconductor layer. The third insulating layer and the second insulating layer in the twelfth via V12 and the thirteenth via V13 may be removed to expose a portion of a surface of the first conductive layer. The third insulating layer in the fourteenth via V14 to the seventeenth via V17 may be removed to expose a portion of a surface of the second conductive layer.

(6) A third conductive layer is formed. In some examples, a third conductive thin film is deposited on the base substrate on which the aforementioned patterns are formed, and the third conductive thin film is patterned using a patterning process to form a third conductive layer disposed on the third insulating layer. In some examples, the third conductive layer may also be referred to as a first source-drain metal layer.

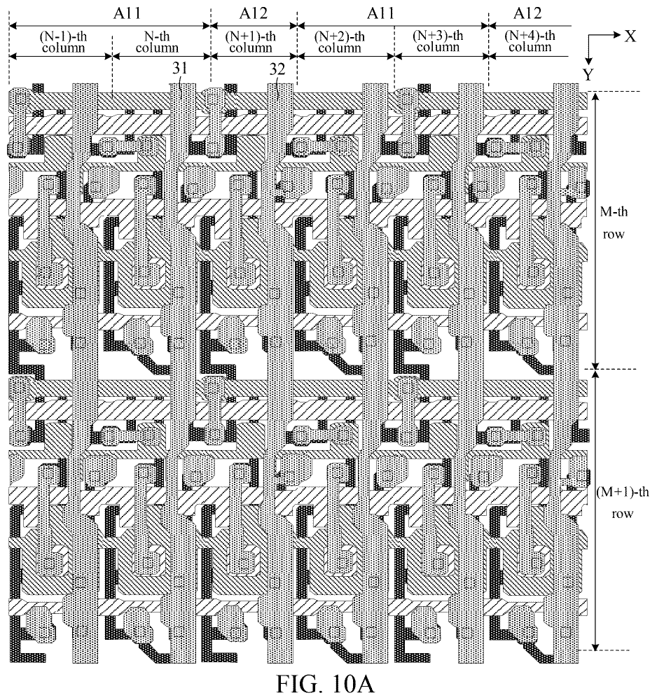

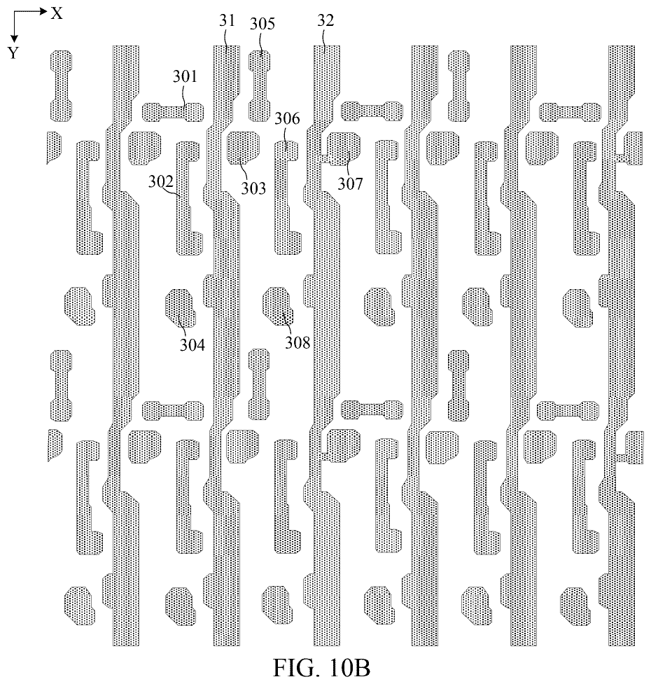

FIG. 10A is a schematic plan view of the display substrate after a third conductive layer is formed in FIG. 5. FIG. 10B is a schematic diagram of the third conductive layer in FIG. 10A. In some examples, as shown in FIGS. 10A and 10B, the third conductive layer of the first circuit unit may include at least a plurality of connection electrodes of the first pixel circuit (including, for example, a first connection electrode 301, a second connection electrode 302, a third connection electrode 303, and a fourth connection electrode 304), and a first voltage line 31. The third conductive layer of the second circuit unit may include at least a plurality of connection electrodes of the dummy pixel circuit (including, for example, a fifth connection electrode 305, a sixth connection electrode 306, a seventh connection electrode 307, and an eighth connection electrode 308), and a second voltage line 32.

In some examples, the first connection electrode 301 may be substantially in a shape of a strip extending in the first direction X. One end of the first connection electrode 301 may be electrically connected to a first region of the first active layer of the first pixel circuit through the first via V1, and the other end of the first connection electrode may be electrically connected to the first initial signal line INIT1(m) through the sixteenth via V16.

In some examples, the second connection electrode 302 may be substantially in a shape of a strip extending in the first direction X. One end of the second connection electrode 302 may be electrically connected to a first region of the second active layer of the first pixel circuit through the second via V2, and the other end of the second connection electrode may be electrically connected to the first plate 181 of the storage capacitor of the first pixel circuit through the twelfth via V12.

In some examples, the third connection electrode 303 may have a substantially rectangular shape. The third connection electrode 303 may be electrically connected to a first region of the fourth active layer of the first pixel circuit through the third via V3.

In some examples, the fourth connection electrode 304 may have a substantially rectangular shape. The fourth connection electrode 304 may be electrically connected to a second region of the sixth active layer of the first pixel circuit through the fifth via V5.

In some examples, the first voltage line 31 may be substantially in a shape of a bending line with a main body portion extending in the second direction Y. The first voltage line 31 may be electrically connected to the second plate 182 of the first pixel circuit through the fourteenth via V14, and may also be electrically connected to a first region of the fifth active layer of the first pixel circuit through the fourth via V4.

In some examples, the fifth connection electrode 305 may be substantially in a shape of a strip extending in the second direction Y. One end of the fifth connection electrode 305 may be electrically connected to the second initial signal line INIT2(m) through the seventeenth via V17, and the other end of the fifth connection electrode may be electrically connected to a first region of the seventh active layer of the first pixel circuit of a previous row through the sixth via V6.

In some examples, the sixth connection electrode 306 may be substantially in a shape of a strip extending in the second direction Y. One end of the sixth connection electrode 306 may be electrically connected to a first region of the second active layer of the dummy pixel circuit through the eighth via V8, and the other end of the sixth connection electrode may be electrically connected to the first plate 281 of the dummy pixel circuit through the thirteenth via V13.

In some examples, the seventh connection electrode 307 may have a substantially rectangular shape. The seventh connection electrode 307 may be electrically connected to a first region of the fourth active layer of the dummy pixel circuit through the ninth via V9.

In some examples, the eighth connection electrode 308 may have a substantially rectangular shape. The eighth connection electrode 308 may be electrically connected to a second region of the sixth active layer of the dummy pixel circuit through the eleventh via V11. In some examples, the second voltage line 32 may be substantially in a shape of a bending line with a main body portion extending along the second direction Y. The second voltage line 32 may be electrically connected to the second plate 282 of the dummy pixel circuit through the fifteenth via V15, and may also be electrically connected to a first region of the fifth active layer of the dummy pixel circuit through the tenth via V10. The second voltage line 32 and the seventh connection electrode 307 may be of an interconnected integral structure.

(7) A fourth insulating layer and a fifth insulating layer are formed. In some examples, a fourth insulating thin film is deposited on the base substrate on which the aforementioned patterns are formed, then a fifth insulating thin film is coated, and the fifth insulating thin film and the fourth insulating thin film are sequentially patterned using a patterning process to form a fourth fifth insulating layer and a fifth insulating layer. The fourth insulating layer and the fifth insulating layer of each circuit unit may be provided with a plurality of vias. In some examples, the fourth insulating layer may also be referred to as a passivation layer and the fifth insulating layer may also be referred to as a first planarization layer.

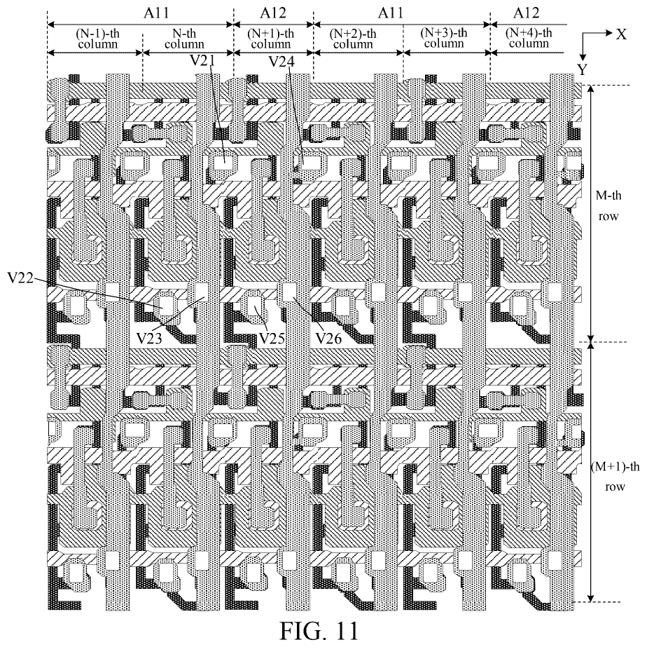

FIG. 11 is a schematic plan view of a display substrate after a fifth insulating layer is formed in FIG. 5. In some examples, as shown in FIG. 11, the plurality of vias of the first circuit unit may include at least a twenty-first via V21, a twenty-second via V22, and a twenty-third via V23. The plurality of vias of the second circuit unit may include at least a twenty-fourth via V24, a twenty-fifth via V25, and a twenty-sixth via V26. The fifth insulating layer and the fourth insulating layer within the twenty-first via V21 to the twenty-sixth via V26 may be removed to expose a portion of a surface of the third conductive layer.

(8) A fourth conductive layer is formed. In some examples, a fourth conductive thin film is deposited on the base substrate on which the aforementioned patterns are formed, and the fourth conductive thin film is patterned using a patterning process to form a fourth conductive layer disposed on the fifth insulating layer. In some examples, the fourth conductive layer may also be referred to as a second source-drain metal layer.

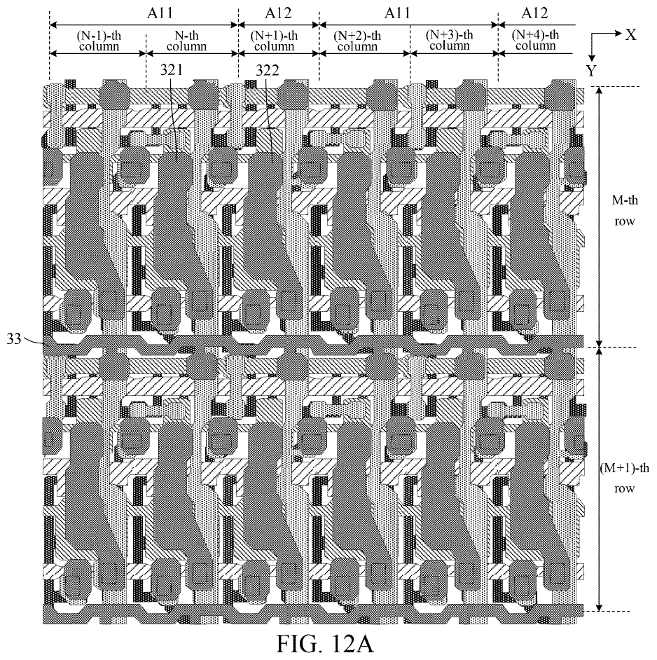

FIG. 12A is a schematic plan view of the display substrate after a fourth conductive layer in FIG. 5 is formed. FIG. 12B is a schematic diagram of a fourth conductive layer in FIG. 12A. In some examples, as shown in FIGS. 12A and 12B, the fourth conductive layer of the first circuit unit may include at least a plurality of connection electrodes of the first pixel circuit (including, for example, an eleventh connection electrode 311 and a twelfth connection electrode 312), and a first shielding electrode 321 of the first pixel circuit. The fourth conductive layer of the second circuit unit may include at least a plurality of connection electrodes of the dummy pixel circuit (including, for example, a thirteenth connection electrode 313 and a fourteenth connection electrode 314), and a second shielding electrode 322 of the dummy pixel circuit.

In some examples, the eleventh connection electrode 311 may be substantially in a shape of a rectangle, and corners of the rectangle may be provided with chamfers. The eleventh connection electrode 311 may be electrically connected to the third connection electrode 303 of the first pixel circuit through the twenty-first via V21, to realize an electrical connection to the fourth transistor of the first pixel circuit.

In some examples, the twelfth connection electrode 312 may be substantially in a shape of a rectangle, and corners of the rectangle may be provided with chamfers. The twelfth connection electrode 312 may be electrically connected to the fourth connection electrode 304 of the first pixel circuit through the twenty-second via V22 to realize an electrical connection to the sixth transistor of the first pixel circuit.

In some examples, the thirteenth connection electrode 313 may be substantially in a shape of a rectangle, and corners of the rectangle may be provided with chamfers. The thirteenth connection electrode 313 may be electrically connected to the seventh connection electrode 307 of the dummy pixel circuit through the twenty-fourth via V24, to realize an electrical connection to the fourth transistor of the dummy pixel circuit. Since the seventh connection electrode 307 and the second voltage line 32 are of an interconnected integral structure, the thirteenth connection electrode 313 is also electrically connected to the second voltage line 32.

In some examples, the fourteenth connection electrode 314 may be substantially in a shape of a rectangle, and corners of the rectangle may be provided with chamfers. The fourteenth connection electrode 314 may be electrically connected to the eighth connection electrode 308 of the dummy pixel circuit through the twenty-fifth via V25 to realize an electrical connection to the sixth transistor of the dummy pixel circuit.

In some examples, the first shielding electrode 321 may be substantially in a shape of a bending line extending in the second direction Y. The first shielding electrode 321 may be electrically connected to the first voltage line 31 through the twenty-third via V23. An orthographic projection of the first shielding electrode 321 on the base substrate may cover an orthographic projection of the second connection electrode 302 on the base substrate. Since the second connection electrode 302 connects a second region of the first active layer, a first region of the second active layer, a gate of the third transistor, and a first plate of the storage capacitor of the first pixel circuit, the second connection electrode 302 may serve as a first node of the first pixel circuit. The first shielding electrode 321 is electrically connected to the first voltage line 31, which can realize the transmission of a constant first voltage signal, can shield the first node from other signals in the first pixel circuit, and can avoid other signals (such as data voltage jumps) from affecting the voltage of the first node of the first pixel circuit, which can improve the display effect.

In some examples, the second shielding electrode 322 may be substantially in a shape of a bending line extending in the second direction Y. The second shielding electrode 322 may be electrically connected to the second voltage line 32 through the twenty-sixth via V26. An orthographic projection of the second shielding electrode 322 on the base substrate may cover an orthographic projection of the sixth connection electrode 306 on the base substrate. The second shielding electrode 322 may shield the first node of the dummy pixel circuit from other signals in the dummy pixel circuit.

In some examples, a third voltage line 33 may be disposed between adjacent unit rows. The third voltage line 33 may be in a shape of a bending line with a main body portion extending in the first direction X. The third voltage line 33 may be located at a side of the twelfth connection electrode 312 and the fourteenth connection electrode 314 in the second direction Y. A plurality of first connection blocks 33-1 may be provided on a side of the third voltage line 33 away from the twelfth connection electrode 312 and the fourteenth connection electrode 314. A first connection block 33-1 may be substantially in a shape of a rectangle. A first end of each of the first connection blocks 33-1 is connected to the third voltage line 33, and a second end thereof may extend into one circuit unit in the second direction Y. The plurality of first connection blocks 33-1 may be provided at intervals along the first direction X. The plurality of first connection blocks 33-1 and the third connection line 33 may be of an interconnected integral structure. The first connection block 33-1 may be configured to be subsequently electrically connected to a fourth voltage line extending in the second direction Y. In this example, by providing the third voltage line, a lateral transmission path for a second voltage signal can be formed.

(9) A sixth insulating layer is formed. In some examples, a sixth insulating thin film is coated on the base on which the aforementioned patterns are formed, and the sixth insulating thin film is patterned using a patterning process to form a sixth insulating layer. The sixth insulating layer of each circuit unit may be provided with a plurality of vias. In some examples, the sixth insulating layer may also be referred to as a second planarization layer.

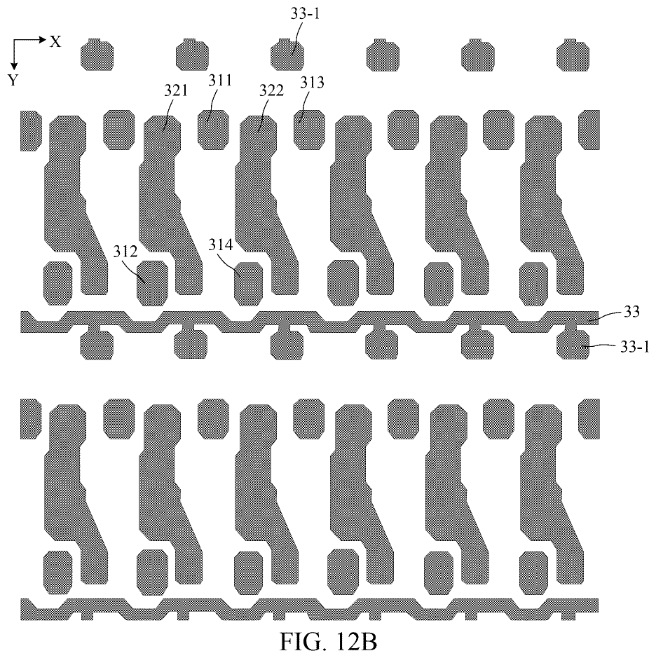

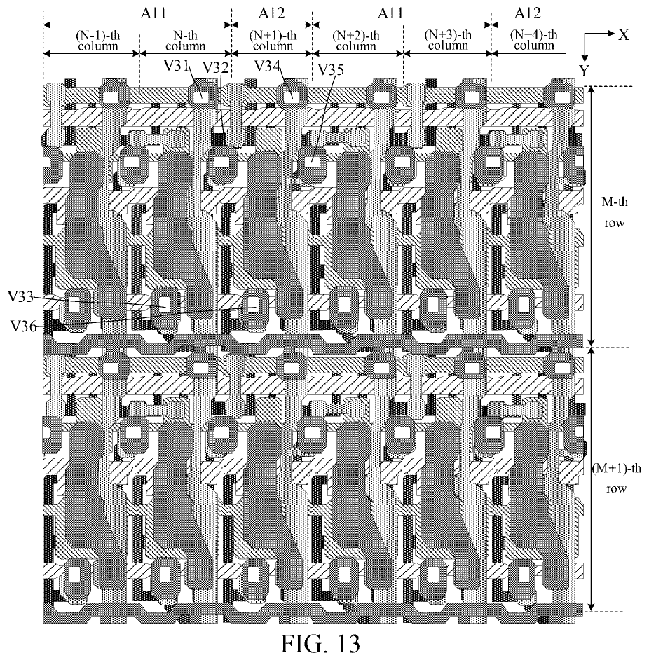

FIG. 13 is a schematic plan view of a display substrate after a sixth insulating layer is formed in FIG. 5. In some examples, as illustrated in FIG. 13, the plurality of vias of the first circuit unit may include at least a thirty-first via V31, a thirty-second via V32, and a thirty-third via V33. The plurality of vias of the second circuit unit may include at least a thirty-fourth via V34, a thirty-fifth via V35, and a thirty-sixth via V36. The sixth insulating layer within the thirty-first via V31 to the thirty-sixth via V36 may be removed to expose a portion of a surface of the fourth conductive layer.

(10) A fifth conductive layer is formed. In some examples, a fifth conductive thin film is deposited on the base substrate on which the aforementioned patterns are formed, and the fifth conductive thin film is patterned using a patterning process to form a fifth conductive layer disposed on the sixth insulating layer. In some examples, the fifth conductive layer may also be referred to as a third source-drain metal layer.

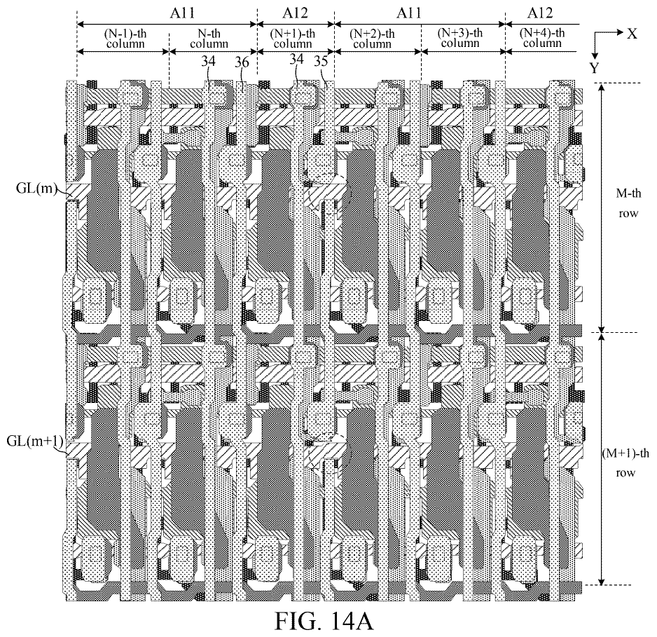

FIG. 14A is a schematic plan view of a display substrate after a fifth conductive layer is formed in FIG. 5. FIG. 14B is a schematic diagram of the fifth conductive layer in FIG. 14A. In some examples, as shown in FIGS. 14A and 14B, the fifth conductive layer of the first circuit unit may include at least a fifteenth connection electrode 315, a fourth voltage line 34, and a first data line 36. The fifth conductive layer of the second circuit unit may include at least a sixteenth connection electrode 316, a fourth voltage line 34, and a dummy data line 35.

In some examples, the fifteenth connection electrode 315 may be substantially in a shape of a rectangle, and corners of the rectangle may be provided with chamfers. The fifteenth connection electrode 315 may be electrically connected to the twelfth connection electrode 312 through the thirty-third via V33 to realize an electrical connection to the second region of the sixth active layer of the first pixel circuit.

In some examples, the sixteenth connection electrode 316 may be substantially in a shape of a rectangle, and corners of the rectangle may be provided with chamfers. The sixteenth connection electrode 315 may be electrically connected to the fourteenth connection electrode 314 through the thirty-sixth via V36 to realize an electrical connection to the second region of the sixth active layer of the dummy pixel circuit.

In some examples, the fourth voltage line 34 may be substantially in a shape of a bending line with a main body portion extending in the second direction Y. The fourth voltage line 34 in the first circuit unit may be electrically connected to the first connection block 33-1 through the thirty-first via V31 to realize an electrical connection to the third voltage line 33. The fourth voltage line 34 in the second circuit unit may be electrically connected to the first connection block 33-1 through the thirty-fourth via V34 to realize an electrical connection to the third voltage line 33. In the present example, the third voltage line 33 with the main body portion extending in the first direction X and the fourth voltage line 34 with the main body portion extending in the second direction Y are connected to each other, and a mesh structure for transmitting the second voltage signal can be formed, which can not only effectively reduce the transmission voltage drop of the second voltage signal, but also improve the uniformity of the second voltage signal in the display substrate.

In some examples, the first data line 36 may be substantially in a shape of a bending line with a main body portion extending in the second direction Y. The first data line 36 may be electrically connected to the eleventh connection electrode 311 through the thirty-second via V32 to realize an electrical connection to the fourth transistor of the first pixel circuit, and is configured to provide a data signal to the first pixel circuit.

In some examples, the dummy data line 35 may be substantially in a structure of a strip with a main body portion extending in the second direction Y. In one unit column in which a second circuit unit is located, a plurality of dummy data lines 35 may be sequentially arranged in the second direction Y. A first fracture K1 is provided between adjacent dummy data lines 35. The dummy data line 35 may have a first end 351 and a second end 352. The first end 351 of the dummy data line 35 may be electrically connected to the fourth transistor of the dummy pixel circuit through the thirty-fifth via V35 in a second circuit unit, and the second end 352 may extend into an adjacent second circuit unit in the opposite direction of the second direction Y. The first end 351 and the second end 352 of the dummy data line 35 may be adjacent to different scan lines. For example, the first end 351 of a dummy data line 35 is adjacent to the scan line GL(m+1), and the second end thereof is adjacent to the scan line GL(m).

In some examples, a first fracture K1 is provided between a first end 351 of a dummy data line 35 and a second end 352 of an adjacent dummy data line 35. For example, an orthographic projection of the scan line GL(m) on the base substrate may pass through an orthographic projection of the first fracture K1 on the base substrate. The length of the main body portion of the scan line GL(m) in the second direction Y may be smaller than the length of the first fracture K1 in the second direction Y. By providing the first fracture K1, it can be made possible that an orthographic projection of the dummy data line 35 on the base substrate does not overlap with an orthographic projection of the scan line on the base substrate (as shown at the position indicated by the dotted box in FIG. 14A).

In this example, the dummy data line 35 may be electrically connected to the second voltage line 32 that transmits the first voltage signal through the thirteenth connection electrode 313 and the seventh connection electrode 307, which can avoid a trace floating connection affecting the circuit stability. Furthermore, a first fracture is provided between adjacent dummy data lines 35, so that the dummy data lines are disconnected at the position of the scan line, which can reduce overlap between the scan line and the dummy data line of the dummy pixel circuit in the second circuit unit, thereby reducing the load of the scan line and contributing to improving the lateral poor display of the display substrate. Since the dummy pixel circuit is not electrically connected to any light emitting element, the dummy pixel circuit is connected to the second voltage line through the dummy data line, and does not affect the normal display of the display substrate.

So far, the drive circuit layer may be formed in the first display region of the display substrate. For example, the drive circuit layer may include a semiconductor layer, a first insulating layer, a first conductive layer, a second insulating layer, a second conductive layer, a third insulating layer, a third conductive layer, a fourth insulating layer, a fifth insulating layer, a fourth conductive layer, a sixth insulating layer, and a fifth conductive layer disposed on the base substrate. In some examples, after the fifth conductive layer is formed, the second display region may include a first insulating layer, a second insulating layer, a third insulating layer, a fourth insulating layer, a fifth insulating layer, and a sixth insulating layer stacked on the base substrate.

(11) A seventh insulating layer and a first connection layer are formed. In some examples, a seventh insulating thin film is coated on the base substrate on which the aforementioned patterns are formed, and the seventh insulating thin film is patterned using a patterning process to form a seventh insulating layer; Subsequently, a first transparent conductive thin film is deposited, and the first transparent conductive thin film is patterned using a patterning process to form a first connection layer disposed on the seventh insulating layer. The seventh insulating layer of each circuit unit may be provided with a via. In some examples, the seventh insulating layer may also be referred to as a third planarization layer.

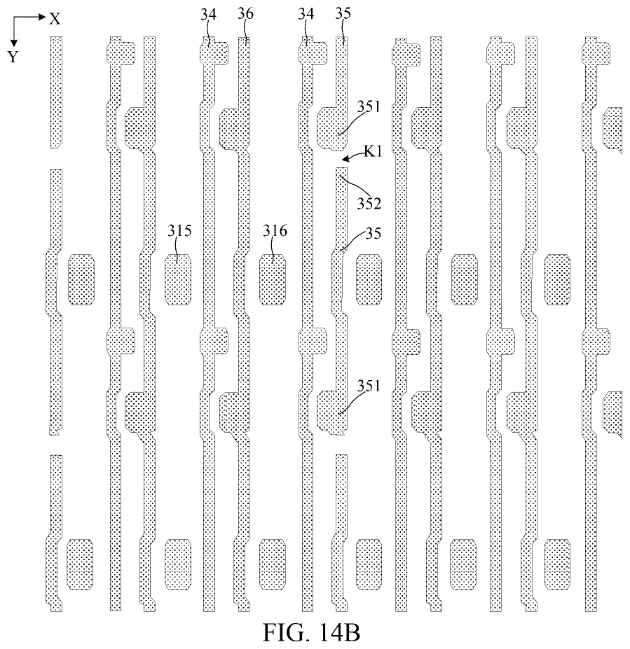

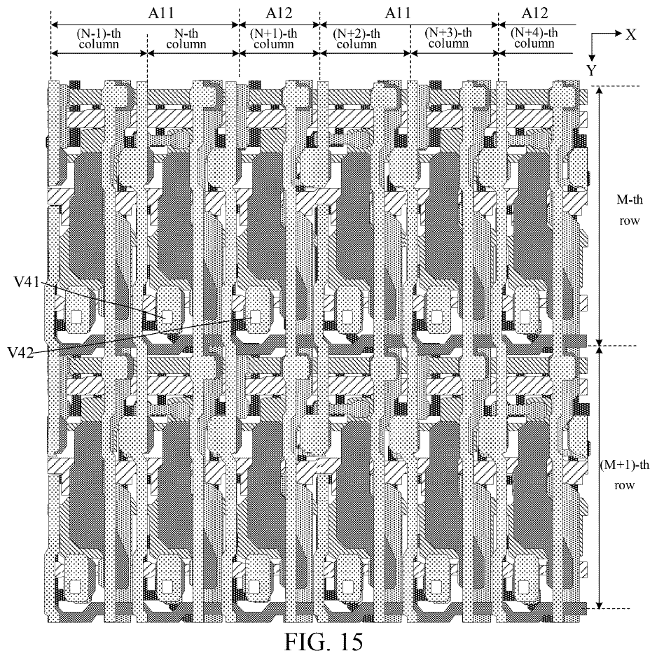

FIG. 15 is a schematic plan view of a display substrate after a seventh insulating layer is formed in FIG. 5. In some examples, as shown in FIG. 15, the vias of the first circuit unit may include at least a forty-first via V41. The vias of the second circuit unit may include at least a forty-second via V42.

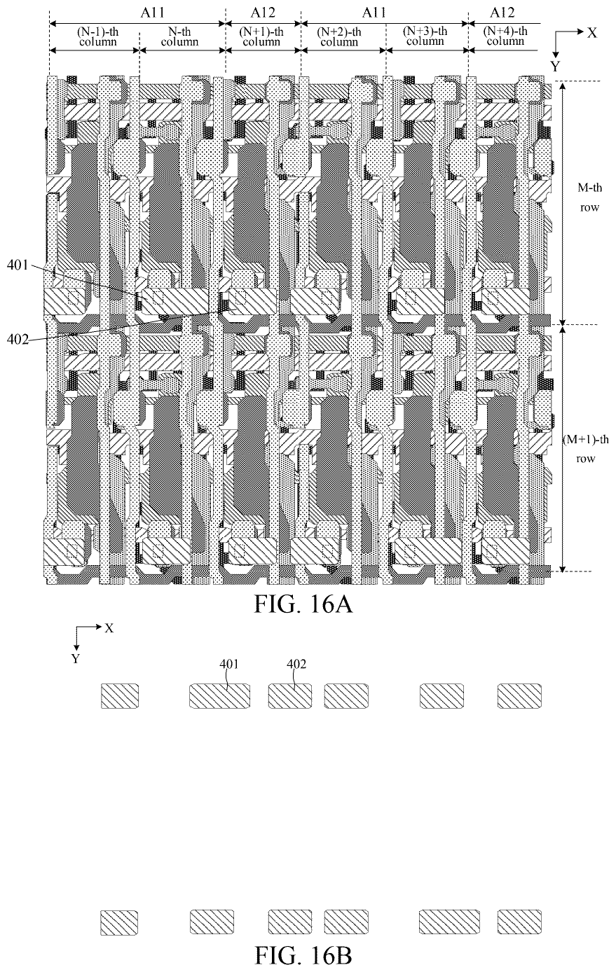

FIG. 16A is a schematic plan view of the display substrate after a first connection layer is formed in FIG. 5. FIG. 16B is a schematic diagram of the first connection layer in FIG. 16A. In some examples, as shown in FIGS. 16A and 16B, the first connection layer of the first circuit unit may include at least a first anode connection electrode 401. The first connection layer of the second circuit unit may include at least a first dummy connection electrode 402. The first anode connection electrode 401 may be electrically connected to the fifteenth connection electrode 315 through the forty-first via V41. The first dummy connection electrode 402 may be electrically connected to the sixteenth connection electrode 316 through the forty-second via V42.

(12) An eighth insulating layer and a second connection layer are formed. In some examples, an eighth insulating thin film is coated on the base substrate on which the aforementioned patterns are formed, and the eighth insulating thin film is patterned using a patterning process to form an eighth insulating layer; Subsequently, a second transparent conductive thin film is deposited, and the second transparent conductive thin film is patterned using a patterning process to form a second connection layer disposed on the eighth insulating layer. The eighth insulating layer of each circuit unit may be provided with a via. In some examples, the eighth insulating layer may also be referred to as a fourth planarization layer.

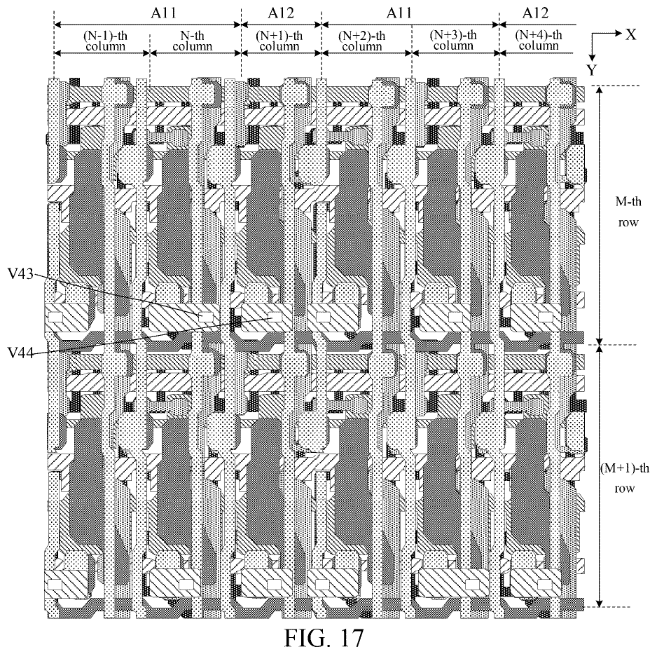

FIG. 17 is a schematic plan view of a display substrate after an eighth insulating layer is formed in FIG. 5. In some examples, as shown in FIG. 17, the vias of the first circuit unit may include at least a forty-third via V43. The vias of the second circuit unit may include at least a forty-fourth via V44.

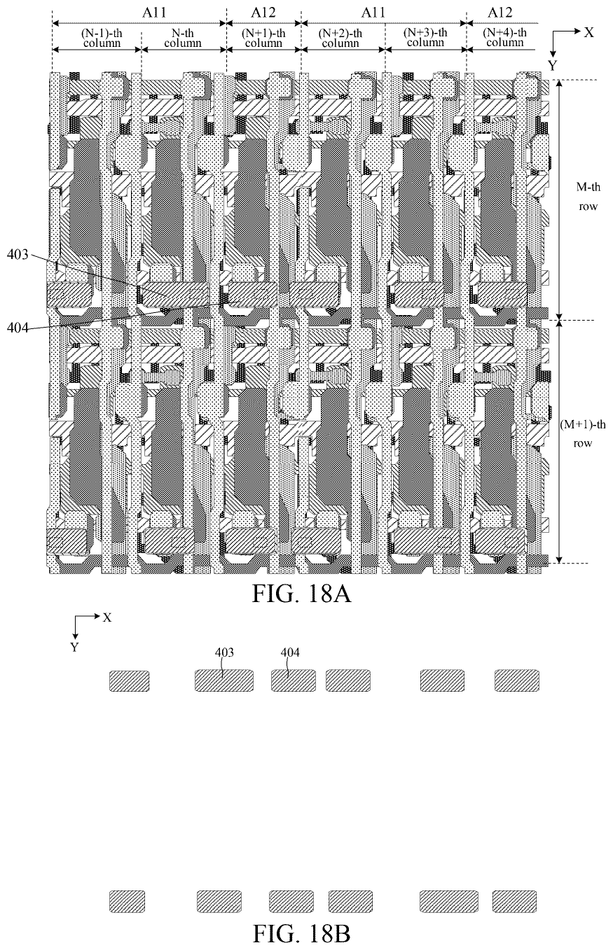

FIG. 18A is a schematic plan view of the display substrate after a second connection layer is formed in FIG. 5. FIG. 18B is a schematic diagram of the second connection layer in FIG. 18A. In some examples, as shown in FIGS. 18A and 18B, the second connection layer of the first circuit unit may include at least a second anode connection electrode 403. The second connection layer of the second circuit unit may include at least a second dummy connection electrode 404. The second anode connection electrode 403 may be electrically connected with the first anode connection electrode 401 through the forty-third via V43. The second dummy connection electrode 404 may be electrically connected to the first dummy connection electrode 401 through the forty-fourth via V44.

(13) A ninth insulating layer, a third connection layer, and a tenth insulating layer are formed. In some examples, a ninth insulating thin film is coated on the base substrate on which the aforementioned patterns are formed, and the ninth insulating thin film is patterned using a patterning process to form a ninth insulating layer; subsequently, a third transparent conductive thin film is deposited, and the third transparent conductive thin film is patterned using a patterning process to form a third connection layer disposed on the ninth insulating layer; subsequently, a tenth insulating thin film is coated, and the tenth insulating thin film is patterned using a patterning process to form a tenth insulating layer. The ninth insulating layer of each circuit unit may be provided with a via. The tenth insulating layer of each first circuit unit may be provided with a via. In some examples, the ninth insulating layer may also be referred to as a fifth planarization layer and the tenth insulating layer may also be referred to as a sixth planarization layer.

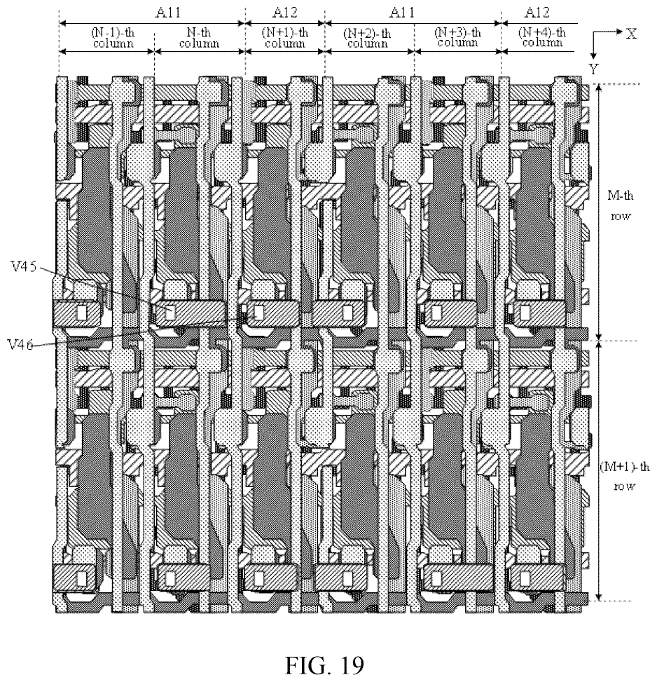

FIG. 19 is a schematic plan view of a display substrate after a ninth insulating layer is formed in FIG. 5. In some examples, as shown in FIG. 19, the vias of the first circuit unit may include at least a forty-fifth via V45. The vias of the second circuit unit may include at least a forty-sixth via V46.

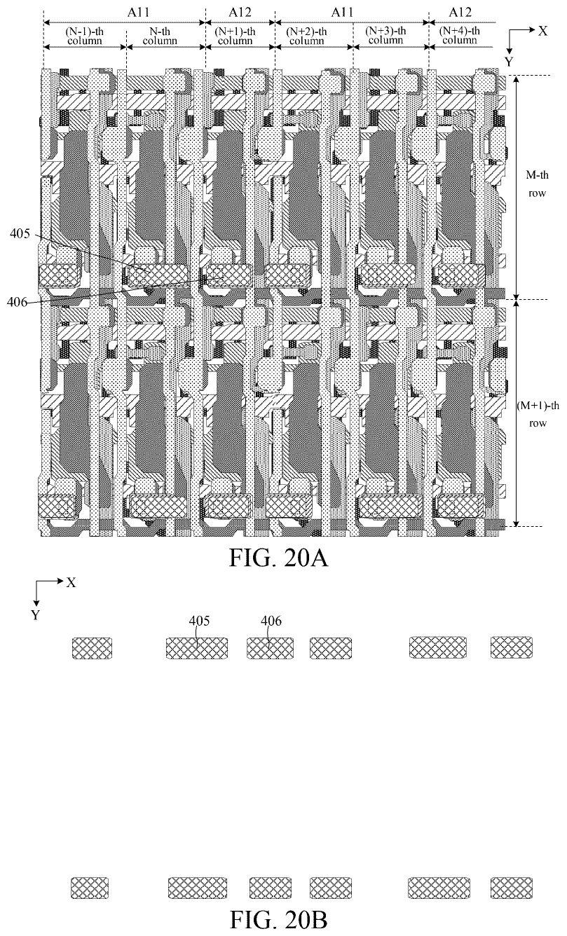

FIG. 20A is a schematic plan view of the display substrate after a third connection layer is formed in FIG. 5. FIG. 20B is a schematic diagram of the third connection layer in FIG. 20A. In some examples, as shown in FIGS. 20A and 20B, the third connection layer of the first circuit unit may include at least a third anode connection electrode 405. The third connection layer of the second circuit unit may include at least a third dummy connection electrode 406. The third anode connection electrode 405 is electrically connected with the second anode connection electrode 403 through the forty-fifth via V45. The third dummy connection electrode 406 may be electrically connected to the second dummy connection electrode 404 through the forty-sixth via V46.

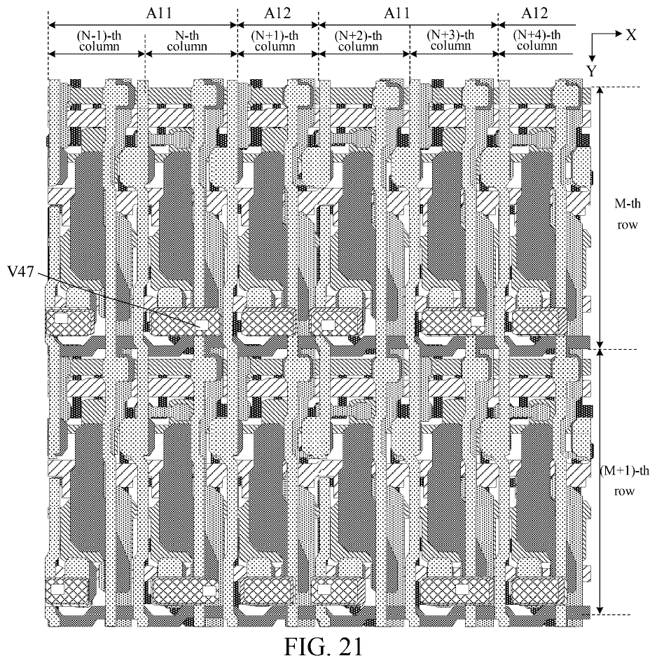

FIG. 21 is a schematic plan view of a display substrate after a tenth insulating layer is formed in FIG. 5. In some examples, as shown in FIG. 21, the vias of the first circuit unit may include at least a forty-seventh via V47. Since the dummy pixel circuit of the second circuit unit does not need to be electrically connected to a light emitting element, the tenth insulating layer of the second circuit unit may not be provided with a via.

By providing the first dummy connection electrode, the second dummy connection electrode, and the third dummy connection electrode in the second circuit unit of the present example, the pattern uniformity of the first connection layer, the second connection layer, and the third connection layer can be ensured, which is beneficial to film layer preparation.

So far, the conductive connection layers of the display substrate can be formed. The conductive connection layers of the present example may include the first connection layer, the second connection layer, and the third connection layer. In some examples, after the tenth insulating layer is formed, the second display region may include the first insulating layer, the second insulating layer, the third insulating layer, the fourth insulating layer, the fifth insulating layer, the sixth insulating layer, the seventh insulating layer, the first connection layer, the eighth insulating layer, the second connection layer, the ninth insulating layer, the third connection layer, and the tenth insulating layer stacked on the base substrate. However, the present embodiment is not limited thereto. In other examples, the conductive connection layers of the display substrate may include one or two connection layers.

(14) A light emitting structure layer is formed. In some examples, an anode thin film is deposited on the base substrate on which the aforementioned patterns are formed, and the anode thin film is patterned using a patterning process to form an anode layer; Subsequently, a pixel definition thin film is coated on the base substrate on which the aforementioned patterns are formed, and a pixel definition layer is formed through mask, exposure, and development processes. The pixel definition layer is formed with a plurality of pixel openings (including, for example, a first pixel opening OP1, a second pixel opening OP2, a third pixel opening OP3, and a fourth pixel opening OP4 as shown in FIG. 5) exposing the anode layer. Subsequently, an organic emitting layer is formed in the pixel openings formed above, and the organic emitting layer is connected with an anode. Subsequently, a cathode thin film is deposited, the cathode thin film is patterned through a patterning process to form a cathode layer, and the cathode layer is electrically connected with the organic light emitting layer.

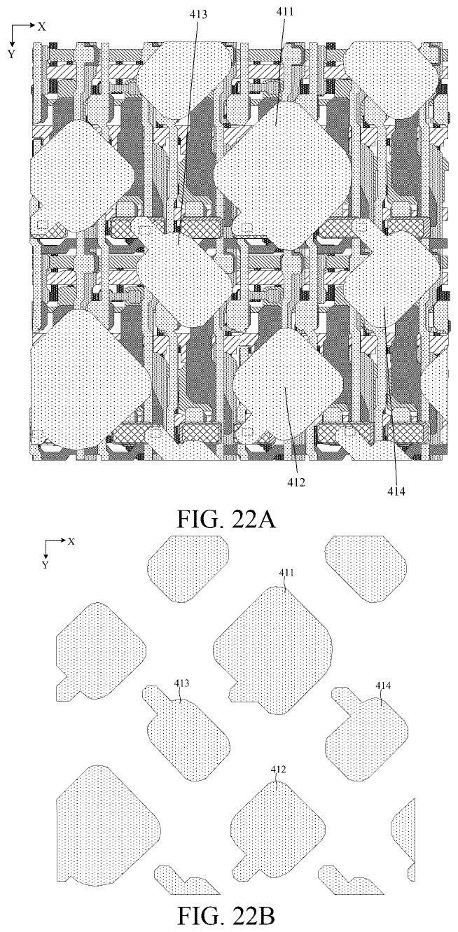

FIG. 22A is a schematic plan diagram of the display substrate after an anode layer is formed in FIG. 5. FIG. 22B is a schematic diagram of the anode layer in FIG. 22A. In some examples, as shown in FIGS. 22A and 22B, the anode layer of the first display region may include a plurality of anodes (e.g., a first anode 411, a second anode 412, a third anode 413, and a fourth anode 414). The first anode 411 may be electrically connected to the first pixel circuit in the circuit unit in the M-th row and the (N+2)-th column; the second anode 412 may be electrically connected to the first pixel circuit in the circuit unit in the (M+1)-th row and the (N+2)-th column; the third anode 413 may be electrically connected to the first pixel circuit in the circuit unit in the M-th row and N-th column; the fourth anode 414 may be electrically connected to the first pixel circuit in the circuit unit in the M-th row and the (N+3)-th column. The dummy pixel circuit in the second circuit unit is not electrically connected to an anode of a light emitting element.

In some examples, an orthographic projection of the anode layer on the base substrate may cover an orthographic projection of the first fracture on the base substrate. By using the anode layer to shield the first fracture, the visibility of appearance can be improved and impacts on visual homogeneity of appearance can be avoided.

In some examples, the first conductive layer, the second conductive layer, the third conductive layer, the fourth conductive layer, and the fifth conductive layer may be made of a metal material, such as, any one or more of silver (Ag), copper (Cu), aluminum (Al), and molybdenum (Mo), or an alloy material of the above metals, such as, an aluminum-neodymium alloy (AlNd), or a molybdenum-niobium alloy (MoNb), which may be in a single layer structure, or a multi-layer composite structure, such as, Mo/Cu/Mo, etc. The first insulating layer, the second insulating layer, the third insulating layer, and the fourth insulating layer may be made of any one or more of Silicon Oxide (SiOx), Silicon Nitride (SiNx), and Silicon Oxynitride (SiON), and may be a single layer, a multi-layer, or a composite layer. The fifth insulating layer to the tenth insulating layer may be made of an organic material, such as polyimide, acrylic, or polyethylene terephthalate. The pixel definition layer may be made of an organic material, such as polyimide, acrylic, or polyethylene terephthalate. The anode layer may be made of a reflective material such as a metal, and the cathode layer may be made of a transparent conductive material. However, the present embodiment is not limited thereto.

A structure and a preparation process of the display substrate of the embodiment are merely illustrative. In some examples, a corresponding structure may be changed and a patterning process may be added or reduced according to actual needs. For example, the provision of the fourth insulating layer or the fifth insulating layer is omitted; as another example, the number of conductive connection layers is reduced. The present embodiment is not limited thereto.

The manufacturing process of this exemplary embodiment may be implemented using an existing mature manufacture equipment, and is compatible well with an existing manufacturing process, simple in process implementation, easy to implement, high in a production efficiency, low in a production cost, and high in a yield.

In the display substrate according to the present example, by providing a first fracture between adjacent dummy data lines in the first display region, the first fracture corresponding to the position of the scan line, and electrically connecting the dummy data line with the second voltage line transmitting the first voltage signal, an overlapping area between the dummy data line connected to the dummy pixel circuit and the scan line can be reduced, thereby reducing the load of the scan line and helping to improve the lateral poor display of the display substrate.

In some examples, the load of the scan line of the present example may be about 10.146 fF, and in a scenario without a fracture-only design for dummy data lines, the load of the scan line may be about 10.157 fF, and the present example may reduce the load of the scan line to some extent.

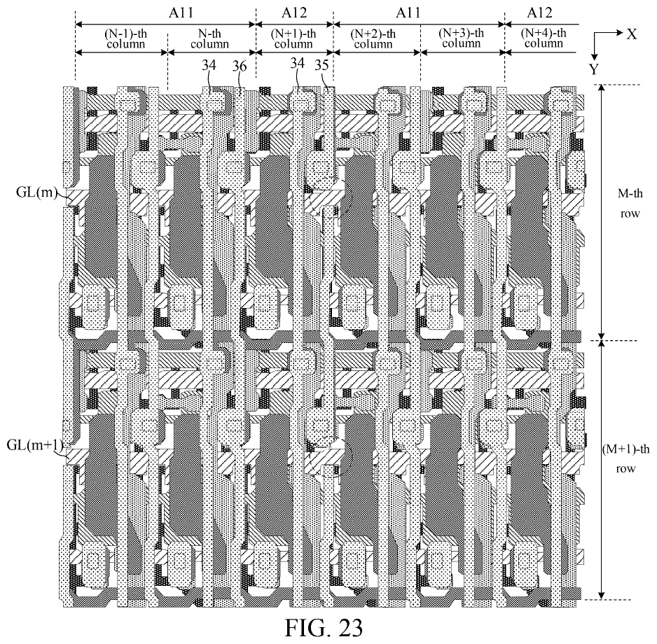

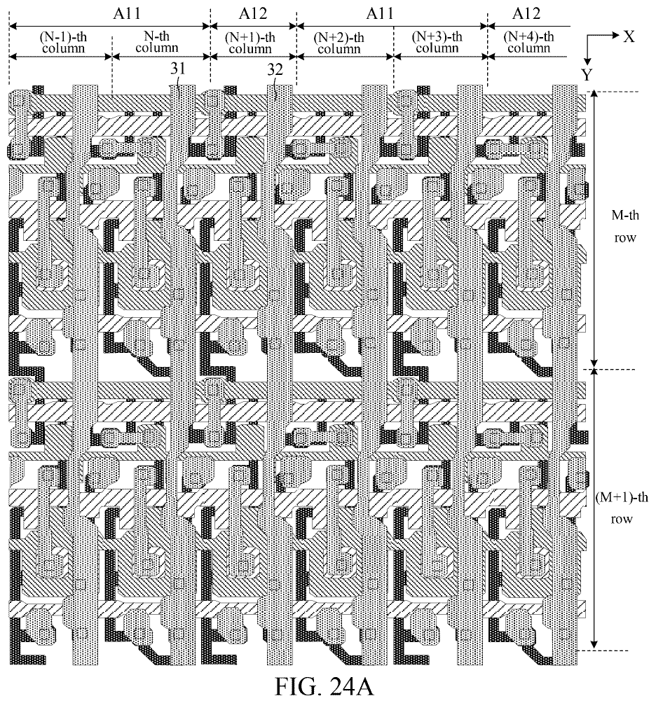

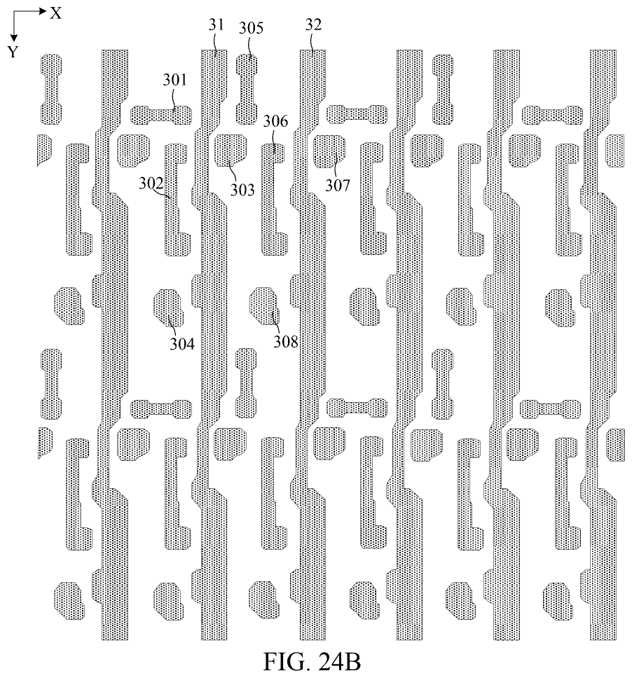

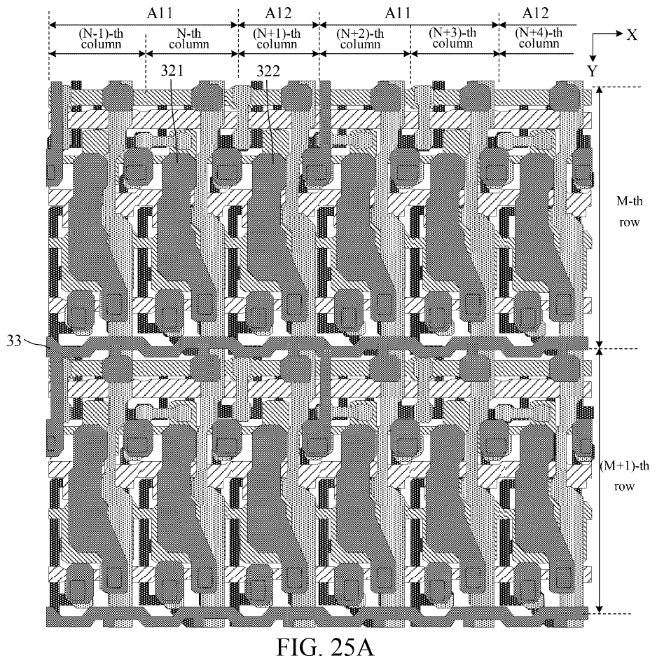

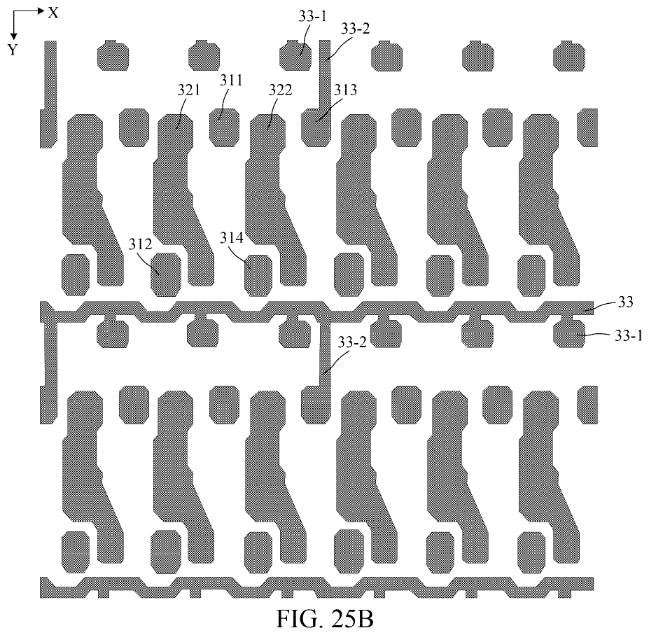

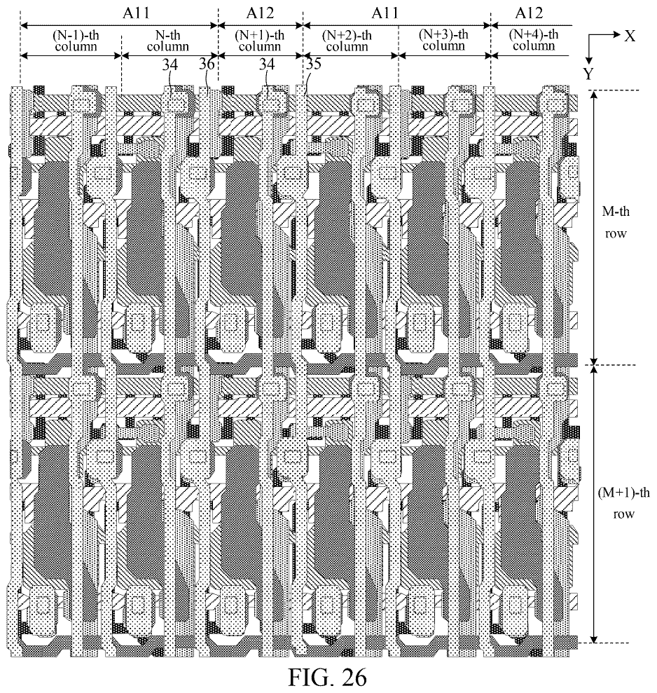

FIG. 23 is another schematic partial plan view of a drive circuit layer of a first display region of a display substrate according to at least one embodiment of the present disclosure. FIG. 24A is a schematic plan view of the display substrate after a third conductive layer is formed in FIG. 23. FIG. 24B is a schematic diagram of the third conductive layer in FIG. 24A. FIG. 25A is a schematic plan view of the display substrate after a fourth conductive layer is formed in FIG. 23. FIG. 25B is a schematic diagram of the fourth conductive layer in FIG. 25A.

In some examples, as illustrated in FIGS. 23 to 26, the drive circuit layer of the first display region may include at least a semiconductor layer, a first insulating layer, a first conductive layer, a second insulating layer, a second conductive layer, a third insulating layer, a third conductive layer, a fourth insulating layer, a fifth insulating layer, a fourth conductive layer, a sixth insulating layer, and a fifth conductive layer disposed on the base substrate. The description of the semiconductor layer to the third insulating layer of the drive circuit layer of the present example can be described with reference to the description of the above-described embodiments, and thus the description thereof will not be repeated here.

In some examples, as shown in FIGS. 24A and 24B, the third conductive layer of the first circuit unit may include at least a plurality of connection electrodes (including, for example, a first connection electrode 301, a second connection electrode 302, a third connection electrode 303, and a fourth connection electrode 304) of the first pixel circuit, and a first voltage line 31. The third conductive layer of the second circuit unit may include at least a plurality of connection electrodes (including, for example, a fifth connection electrode 305, a sixth connection electrode 306, a seventh connection electrode 307, and an eighth connection electrode 308) of the dummy pixel circuit, and a second voltage line 32. Here, the seventh connection electrode 307 is provided independently of the second voltage line 32, and there is no connection relationship between them.

In some examples, as shown in FIGS. 25A and 25B, the fourth conductive layer of the first circuit unit may include at least a plurality of connection electrodes of the first pixel circuit (including, for example, an eleventh connection electrode 311 and a twelfth connection electrode 312), and a first shielding electrode 321 of the first pixel circuit. The fourth conductive layer of the second circuit unit may include at least a plurality of connection electrodes of the dummy pixel circuit (including, for example, a thirteenth connection electrode 313 and a fourteenth connection electrode 314), and a second shielding electrode 322 of the dummy pixel circuit.

In some examples, a third voltage line 33 may be disposed between adjacent unit rows. The third voltage line 33 may be in a shape of a bending line with a main body portion extending in the first direction X. A plurality of first connection blocks 33-1 and a plurality of second connection blocks 33-2 may be provided on a side of the third voltage line 33 away from the twelfth connection electrode 312 and the fourteenth connection electrode 314. The first connection blocks 33-1 and the second connection blocks 33-2 may be disposed at intervals in the first direction X. A first end of a second connection block 33-2 is connected to the third voltage line 33, and a second end thereof extends into a second circuit unit in the second direction Y, and is connected to the thirteenth connection electrode 313. The third voltage line 33, the first connection blocks 33-1, the second connection blocks 33-2, and the thirteenth connection electrode 313 may be of an interconnected integral structure. Since the thirteenth connection electrode 313 is electrically connected to the fourth transistor of the dummy pixel circuit, by electrically connecting the thirteenth connection electrode 313 to the third voltage line 33, it can be achieved that the fourth transistor of the dummy pixel circuit receives the second voltage signal.

In some examples, as shown in FIG. 23, the fifth conductive layer of the first circuit unit may include at least a fourth voltage line 34, a first data line 36. The fifth conductive layer of the second circuit unit may include at least a fourth voltage line 34 and a dummy data line 35. In one unit column in which the second circuit unit is located, a plurality of dummy data lines 35 may be sequentially arranged in the second direction Y. A first fracture is provided between an adjacent dummy data lines 35 (as shown at the position indicated by the dotted box in FIG. 23).

In this example, the dummy data line 35 may be electrically connected to the thirteenth connection electrode 313, to realize an electrical connection to the third voltage line 33 to receive the second voltage signal. A first fracture is provided between adjacent dummy data lines 35, so that the dummy data lines are disconnected at the position of the scan line, which can reduce overlap between the scan line and the dummy data line of the dummy pixel circuit in the second circuit unit, thereby reducing the load of the scan line and contributing to improving the lateral poor display of the display substrate.

Rest of a structure of the display substrate according to this example may be referred to the description of the aforementioned embodiments, and thus will not be repeated here.

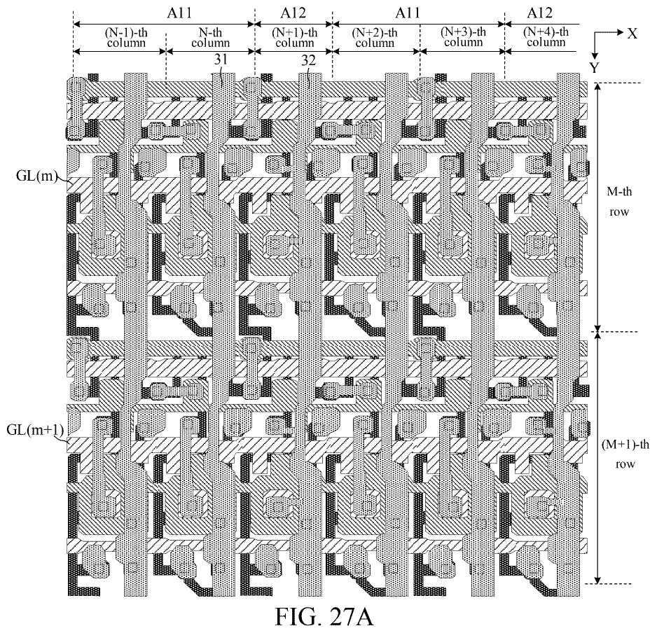

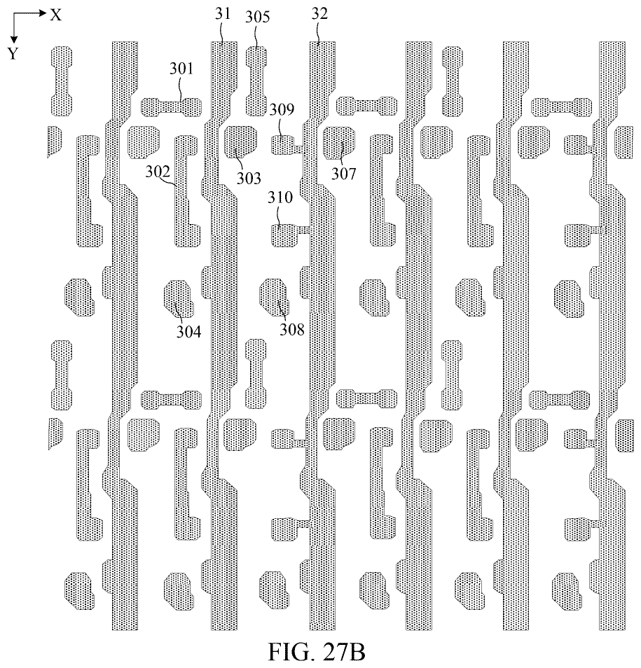

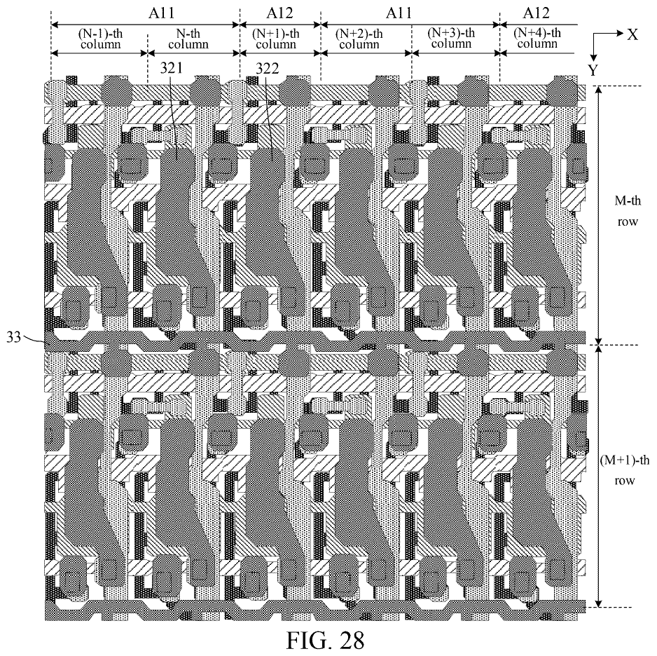

FIG. 26 is another schematic partial plan view of a drive circuit layer of a first display region of a display substrate according to at least one embodiment of the present disclosure FIG. 27A is a schematic plan view of the display substrate after a third conductive layer is formed in FIG. 26. FIG. 27B is a schematic diagram of the third conductive layer in FIG. 27A. FIG. 28 is a schematic plan view of a display substrate after a fourth conductive layer is formed in FIG. 26.

In some examples, as illustrated in FIGS. 26 to 28, the drive circuit layer of the first display region may include at least a semiconductor layer, a first insulating layer, a first conductive layer, a second insulating layer, a second conductive layer, a third insulating layer, a third conductive layer, a fourth insulating layer, a fifth insulating layer, a fourth conductive layer, a sixth insulating layer, and a fifth conductive layer disposed on the base substrate. The description of the semiconductor layer to the third insulating layer of the drive circuit layer of the present example can be described with reference to the description of the above-described embodiments, and thus the description thereof will not be repeated here.

In some examples, as shown in FIGS. 27A and 27B, the third conductive layer of the first circuit unit may include at least a plurality of connection electrodes (including, for example, a first connection electrode 301, a second connection electrode 302, a third connection electrode 303, and a fourth connection electrode 304) of the first pixel circuit, and a first voltage line 31. The third conductive layer of the second circuit unit may include at least a plurality of connection electrodes (including, for example, a fifth connection electrode 305, a seventh connection electrode 307, an eighth connection electrode 308, a ninth connection electrode 309, and a tenth connection electrode 310) of the dummy pixel circuit, and a second voltage line 32.

In some examples, the ninth connection electrode 309 may be electrically connected to a first region of the second active layer of the dummy pixel circuit; the tenth connection electrode 310 may be electrically connected to a first plate of the storage capacitor of the dummy pixel circuit. The ninth connection electrode 309 and the tenth connection electrode 310 may be electrically connected to the second voltage line 32. For example, the ninth connection electrode 309, the tenth connection electrode 310, and the second voltage line 32 may be of an interconnected integral structure. The ninth connection electrode 309 may be located at a side of the scan line GL(m) in an opposite direction of the second direction Y, and the tenth connection electrode 310 may be located at a side of the scan line GL(m) in the second direction Y. Orthographic projections of the ninth connection electrode 309 and the tenth connection electrode 310 on the base substrate is not overlapped with an orthographic projection of the scan line GL(m) on the base substrate.

In some examples, as shown in FIG. 28, the fourth conductive layer of the first circuit unit may include at least a plurality of connection electrodes of the first pixel circuit (including, for example, an eleventh connection electrode and a twelfth connection electrode), and a first shielding electrode 321 of the first pixel circuit. The fourth conductive layer of the second circuit unit may include at least a plurality of connection electrodes (including, for example, a thirteenth connection electrode and a fourteenth connection electrode) of the dummy pixel circuit, and a second shielding electrode 322 of the dummy pixel circuit. A third voltage line 33 may be provided between adjacent unit rows. The description of the fourth conductive layer of the present example can be described with reference to the description of the embodiment shown in FIG. 5, and thus the description thereof will not be repeated here.

In some examples, as shown in FIG. 26, the fifth conductive layer of the first circuit unit may include at least a fourth voltage line 34 and a first data line 36. The fifth conductive layer of the second circuit unit may include at least a fourth voltage line 34 and a dummy data line 35. The fourth voltage line 34, the first data line 36, and the dummy data line 35 may all extend in the second direction Y. An orthographic projection of the dummy data line 35 on the base substrate may overlap with an orthographic projection of the scan line on the base substrate.

In the second circuit unit of the present example, the connection electrodes electrically connected to the first node of the dummy pixel circuit are distributed at two sides of the scan line to avoid overlapping with the scan line, and an overlapping area between the dummy pixel circuit and the scan line can be reduced, thereby reducing the load of the scan line, and helping to improve the lateral poor display of the display substrate. In some examples, the load of the scan line of this example may be about 9.8735 fF, which may reduce the load of the scan line compared to conventional designs.

In other examples, based on the structure of the display substrate of the present example, an orthographic projection of the dummy data line located in the fifth conductive layer the base substrate may not overlap with an orthographic projection of the scan line on the base substrate, for example, the dummy data line may be electrically connected to the second voltage line (as in the embodiment shown in FIG. 5) or the third voltage line (as in the embodiment shown in FIG. 23).

Rest of a structure and a preparation process of the display substrate of this example may be referred to description of the aforementioned embodiments, and thus will not be repeated here.

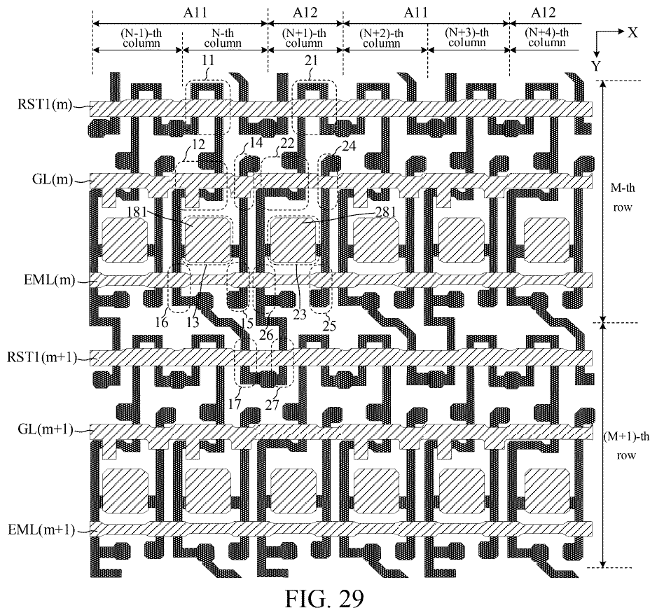

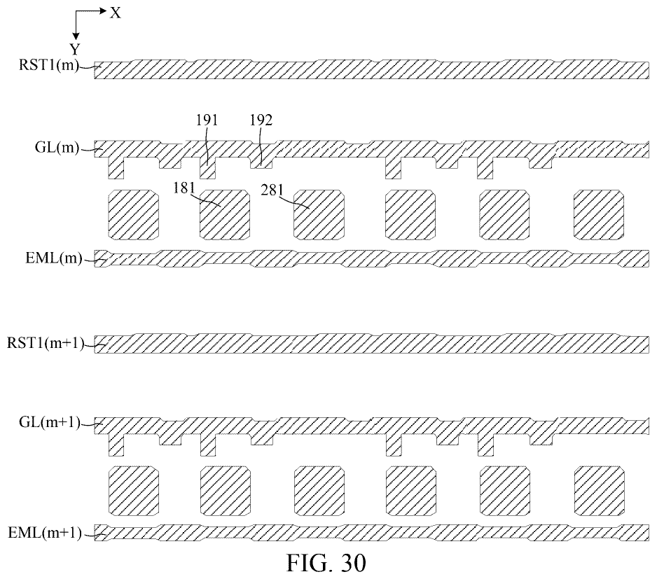

FIG. 29 is another schematic partial plan view of a drive circuit layer of a first display region of a display substrate according to at least one embodiment of the present disclosure. In FIG. 29, only the semiconductor layer and the first conductive layer are illustrated, and the remaining film layers are omitted. FIG. 30 is a schematic diagram of the first conductive layer in FIG. 29.

In some examples, as shown in FIGS. 29 and 30, the first conductive layer of the first circuit unit may include at least: gates of a plurality of transistors of the first pixel circuit (including, for example, gates of the first transistor 11 to the sixth transistor 16 a first pixel circuit of a present row, a gate of the seventh transistor of a first pixel circuit of a previous row) and a first plate 181 of the storage capacitor, a first reset control line (for example, a first reset control line RST1(m) or RST1(m+1)), a scan line (for example, a scan line GL(m) or GL(m+1)), and a light emitting control line (for example, a light emitting control line EML(m) or EML(m+1). In some examples, in the first circuit unit, a first protrusion 191 and a second protrusion 192 may be provided on a side of the scan line GL(m) away from the first reset control line RST1(m). The second transistor 12 of the first pixel circuit has a dual-gate structure.

In some examples, the first conductive layer of the second circuit unit may include at least: gates of a plurality of transistors of the dummy pixel circuit (including, for example, gates of the first transistor 21 to the sixth transistor 26 of a dummy pixel circuit of a present row), a first plate 281 of the storage capacitor, and a gate of the seventh transistor 27 of a dummy pixel circuit of a previous row), a first reset control line (for example, a first reset control line RST1(m) or RST1(m+1)), a scan line (for example, a scan line GL(m) or GL(m+1)), and a light emitting control line (for example, a light emitting control line EML(m) or EML(m+1)). In the second circuit unit, the scan line GL(m) is not provided with a protrusion on a side away from the first reset control line RST1(m). The second transistor 22 of the dummy pixel circuit has a single-gate structure. The length of the gate of the fourth transistor 24 of the dummy pixel circuit in the second direction Y may be smaller than the length of the gate of the fourth transistor 14 of the first pixel circuit in the second direction Y.

In the display substrate of the present example, by reducing the size of the scan line in the second circuit unit, the parasitic capacitance of the scan line can be reduced, thereby reducing the load of the scan line, and contributing to improving the lateral poor display of the display substrate. In some examples, the load of the scan line of this example may be about 8.9955 fF, which may reduce the load of the scan line compared to conventional designs.

In other examples, the load of the scan line may be reduced by only setting the length of the gate of the fourth transistor 24 of the dummy pixel circuit in the second direction Y to be smaller than the length of the gate of the fourth transistor 14 of the first pixel circuit in the second direction Y. Alternatively, the load of the scan line may be reduced by only setting the second transistor 12 of the first pixel circuit to have a dual-gate structure and the second transistor 22 of the dummy pixel circuit to have a single-gate structure.

In other examples, the display substrate of the present example may be combined with the design approach of the foregoing embodiments. For example, the display substrate of the present example is based such that the dummy data line of the dummy pixel circuit is overlapped with scan line and is electrically connected to the second voltage line or the third voltage line.

Rest of a structure and a preparation process of the display substrate of this example may be referred to description of the aforementioned embodiments, and thus will not be repeated here.

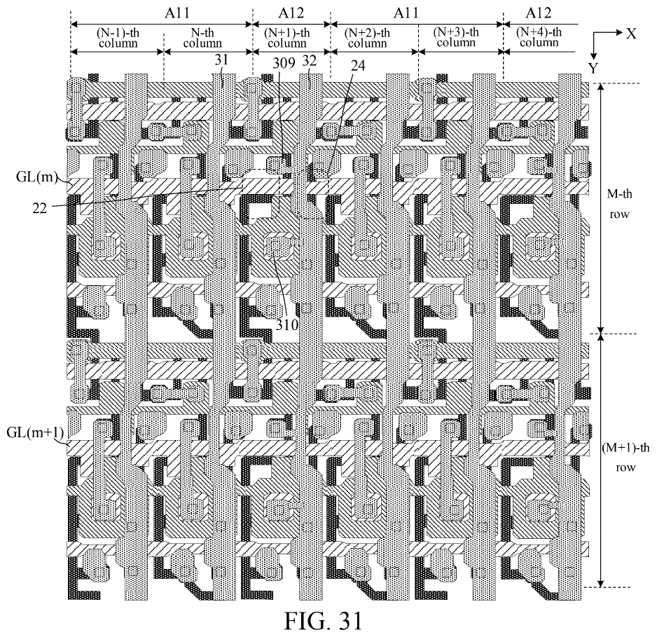

FIG. 31 is another schematic partial plan view of a drive circuit layer of a first display region of a display substrate according to at least one embodiment of the present disclosure. In FIG. 31, the semiconductor layer, the first conductive layer, the second conductive layer, and the third conductive layer are illustrated, and the remaining film layers are omitted.

In some examples, as shown in FIG. 31, the second transistor of the first pixel circuit of the first circuit unit has a dual-gate structure. The second transistor 22 of the dummy pixel circuit of the second circuit unit has a single-gate structure. The length of the gate of the fourth transistor 24 of the dummy pixel circuit in the second direction Y may be smaller than the length of the gate of the fourth transistor of the first pixel circuit in the second direction Y.

In some examples, as shown in FIG. 31, the third conductive layer of the second circuit unit may include at least a ninth connection electrode 309 and a tenth connection electrode 310 of the dummy pixel circuit, and a second voltage line 32. The ninth connection electrode 309 may be electrically connected to a first region of the second active layer of the dummy pixel circuit; the tenth connection electrode 310 may be electrically connected to a first plate of the storage capacitor of the dummy pixel circuit. The ninth connection electrode 309 and the tenth connection electrode 310 may be electrically connected to the second voltage line 32. The ninth connection electrode 309 may be located at a side of the scan line GL(m) in an opposite direction of the second direction Y, and the tenth connection electrode 310 may be located at a side of the scan line GL(m) in the second direction Y. Orthographic projections of the ninth connection electrode 309 and the tenth connection electrode 310 on the base substrate are not overlapped with an orthographic projection of the scan line GL(m) on the base substrate.

In the second circuit unit of the present example, connection electrodes electrically connected to the first node of the dummy pixel circuit are distributed at two sides of the scan line to avoid overlapping with the scan line, and an overlapping area between the dummy pixel circuit and the scan line can be reduced. Furthermore, by reducing the size of the scan line in the second circuit unit, the parasitic capacitance of the scan line can be reduced, thereby reducing the load of the scan line, and contributing to improving the lateral poor display of the display substrate. In some examples, the load of the scan line of the present example may be about 8.7025 fF, which may reduce the load of the scan line compared to conventional designs. In other examples, the display substrate of the present example may be combined with the design approach of the foregoing embodiments. For example, the display substrate of the present example is based such that the dummy data line of the dummy pixel circuit is overlapped with scan line and is electrically connected to the second voltage line or the third voltage line.

Rest of a structure and a preparation process of the display substrate of this example may be referred to description of the aforementioned embodiments, and thus will not be repeated here.

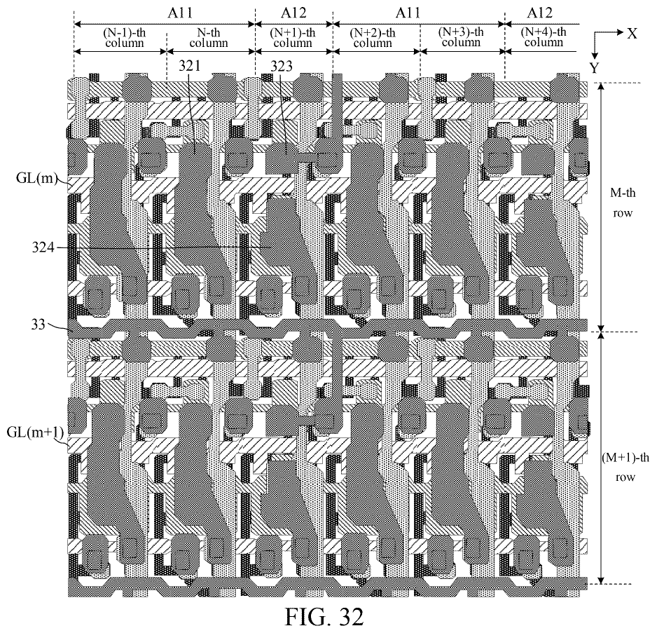

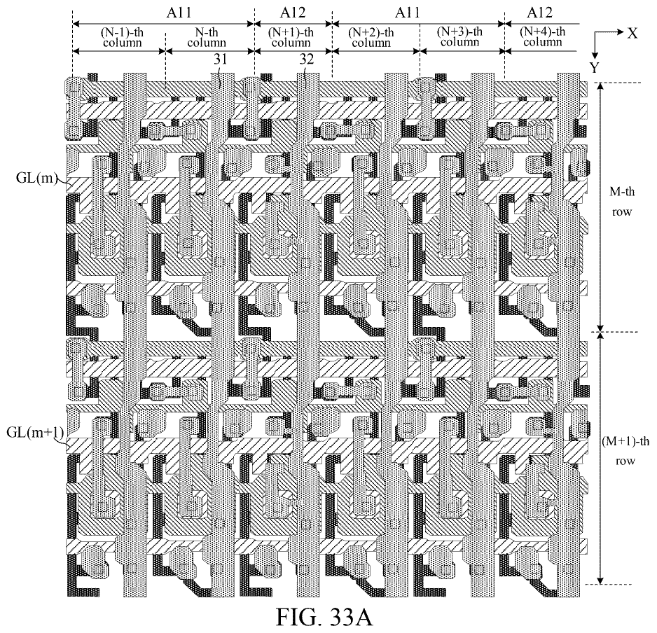

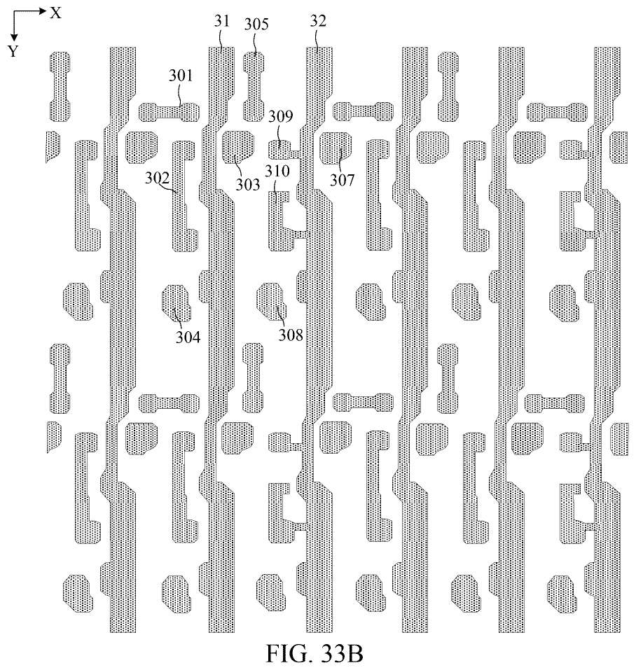

FIG. 32 is another schematic partial plan view of a drive circuit layer of a first display region of a display substrate according to at least one embodiment of the present disclosure. FIG. 33A is a schematic plan view of the display substrate after a third conductive layer is formed in FIG. 32. FIG. 33B is a schematic diagram of the third conductive layer in FIG. 33A. FIG. 34 is a schematic diagram of the fourth conductive layer in FIG. 32.

In some examples, as illustrated in FIGS. 32 to 34, the drive circuit layer of the first display region may include at least a semiconductor layer, a first insulating layer, a first conductive layer, a second insulating layer, a second conductive layer, a third insulating layer, a third conductive layer, a fourth insulating layer, a fifth insulating layer, a fourth conductive layer, a sixth insulating layer, and a fifth conductive layer disposed on the base substrate. The description of the semiconductor layer to the third insulating layer of the drive circuit layer of the present example can be described with reference to the description of the above-described embodiments, and thus the description thereof will not be repeated here.

In some examples, as shown in FIGS. 33A and 33B, the third conductive layer of the first circuit unit may include at least: a plurality of connection electrodes of the first pixel circuit (for example, including a first connection electrode 301, a second connection electrode 302, a third connection electrode 303, and the fourth connection electrode 304) and a first voltage line 31. The third conductive layer of the second circuit unit may include at least a plurality of connection electrodes (including, for example, a fifth connection electrode 305, a seventh connection electrode 307, an eighth connection electrode 308, a ninth connection electrode 309, and a tenth connection electrode 310) of the dummy pixel circuit, and a second voltage line 32.

In some examples, the ninth connection electrode 309 may be electrically connected to a first region of the second active layer of the dummy pixel circuit; the tenth connection electrode 310 may be electrically connected to a first plate of the storage capacitor of the dummy pixel circuit. The ninth connection electrode 309 and the tenth connection electrode 310 may be electrically connected to the second voltage line 32. For example, the ninth connection electrode 309, the tenth connection electrode 310, and the second voltage line 32 may be of an interconnected integral structure. The ninth connection electrode 309 may be located at a side of the scan line GL(m) in an opposite direction of the second direction Y, and the tenth connection electrode 310 may be located at a side of the scan line GL(m) in the second direction Y. Orthographic projections of the ninth connection electrode 309 and the tenth connection electrode 310 on the base substrate are not overlapped with an orthographic projection of the scan line GL(m) on the base substrate.

In some examples, as shown in FIGS. 32 and 34, the fourth conductive layer of the first circuit unit may include at least a plurality of connection electrodes of the first pixel circuit (including, for example, an eleventh connection electrode and a twelfth connection electrode), and a first shielding electrode 321 of the first pixel circuit. The fourth conductive layer of the second circuit unit may include at least a plurality of connection electrodes (including, for example, a thirteenth connection electrode and a fourteenth connection electrode) of the dummy pixel circuit, a third shielding electrode 323, and a fourth shielding electrode 324 of the dummy pixel circuit.

In some examples, within the second circuit unit, the third shielding electrode 323 is connected with the thirteenth connection electrode 313 to enable connection with the third voltage line 33. The third shielding electrode 323, the thirteenth connection electrode 313, the second connection block 33-2, and the third voltage line 33 may be of an interconnected integral structure. An orthographic projection of the third shielding electrode 323 on the base substrate may cover an orthographic projection of the ninth connection electrode 309 on the base substrate, and the orthographic projection of the third shielding electrode 323 on the base substrate is not overlapped with an orthographic projection of the scan line GL(m) on the base substrate.

In some examples, within the second circuit unit, the fourth shielding electrode 324 may be electrically connected to the second voltage line 32 through a via. An orthographic projection of the fourth shielding electrode 324 on the base substrate may cover an orthographic projection of the tenth connection electrode 310 on the base substrate, and the orthographic projection of the fourth shielding electrode 324 on the base substrate is not overlapped with the orthographic projection of the scan line GL(m) on the base substrate.

In the present example, the ninth connection electrode and the tenth connection electrode electrically connected to the first node of the dummy pixel circuit are distributed at two sides of the scan line, and overlapping with the scan line can be avoided; the third shielding electrode and the fourth shielding electrode for shielding the first node of the dummy pixel circuit are distributed at two sides of the scan line, and overlapping with the scan line can be avoided, thereby reducing an overlapping area between the dummy pixel circuit and the scan line, thereby reducing the load of the scan line, and helping to improve the lateral poor display of the display substrate. In some examples, the load of the scan line of this example may be about 9.607 fF, which may reduce the load of the scan line compared to conventional designs.

In other examples, based on the structure of the display substrate of the present example, an orthographic projection of the dummy data line located in the fifth conductive layer the base substrate may not overlap with an orthographic projection of the scan line on the base substrate, for example, the dummy data line may be electrically connected to the second voltage line (as in the embodiment shown in FIG. 5) or the third voltage line (as in the embodiment shown in FIG. 23).

Rest of a structure and a preparation process of the display substrate of this example may be referred to description of the aforementioned embodiments, and thus will not be repeated here.

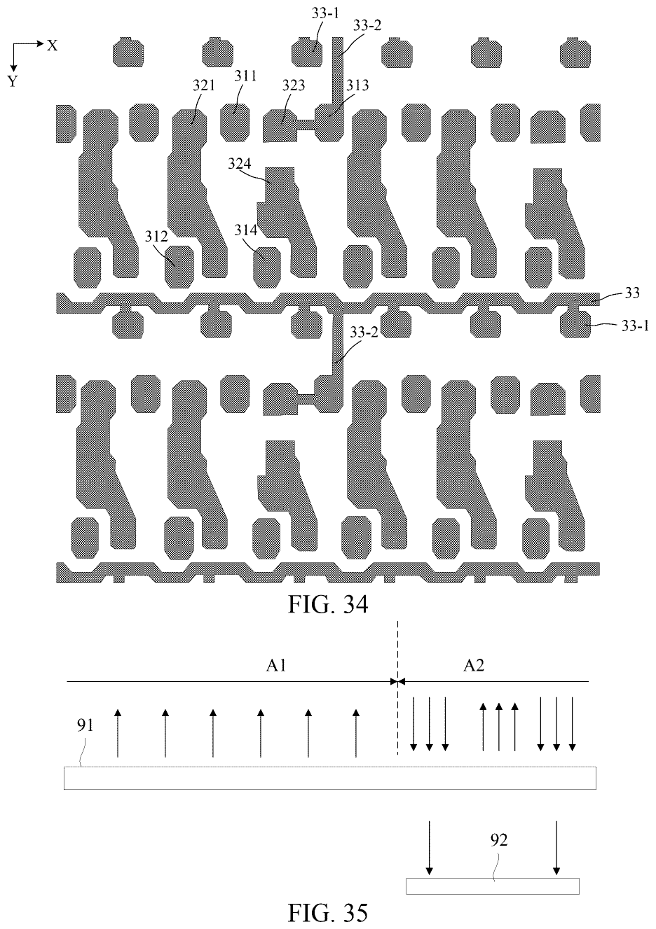

FIG. 35 is a schematic diagram of a display apparatus according to at least one embodiment of the present disclosure. As shown in FIG. 35, the present embodiment provides a display apparatus including a display substrate 91 and a sensor 92 located at a light exit side (a side other than a display surface) of a display structure layer away from the display substrate 91. An orthographic projection of the sensor 92 on the display substrate 91 is overlapped with the second display region A2.

In some examples, the display substrate 91 may be a flexible OLED display substrate, a QLED display substrate, a Micro-LED display substrate, or a Mini-LED display substrate. The display apparatus may be any product or component with a display function such as an OLED display, a unit phone, a tablet, a television, a display, a laptop, a digital photo frame, and a navigator, which is not limited in the embodiments of the present disclosure.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate comprising a first display region;
a drive circuit layer located in the first display region and comprising: a plurality of circuit units constituting a plurality of unit rows and a plurality of unit columns; wherein the plurality of circuit units comprises at least: a plurality of first circuit units and a plurality of second circuit units; a-at least one first circuit unit of the plurality of first circuit units comprises: a first pixel circuit, and a scan line extending in a first direction and a first data line extending in a second direction that are electrically connected to the at least one first pixel circuit; at least one of the second circuit units comprises: a dummy pixel circuit, and a scan line and a dummy data line extending in the second direction that are electrically connected to the dummy pixel circuit; the first direction intersects the second direction;
a light emitting structure layer located on a side of the drive circuit layer away from the base substrate, and comprising a plurality of first light emitting elements located in the first display region, wherein at least one of the first pixel circuits is electrically connected to at least one of the first light emitting elements;
wherein the display substrate satisfies at least one of: an overlapping area of the scan line and the first pixel circuit within the first circuit unit is larger than an overlapping area of the scan line and the dummy pixel circuit within the second circuit unit; and an overlapping area of the scan line and the first data line within the first circuit unit is larger than an overlapping area of the scan line and the dummy data line within the second circuit unit.

2. The display substrate according to claim 1, wherein orthographic projections of the scan line and the dummy data line within the second circuit unit on the base substrate do not overlap.

3. The display substrate according to claim 2, wherein in a unit column where the second circuit unit is located, a plurality of dummy data lines are sequentially arranged in the second direction, a first fracture is provided between dummy data lines adjacent in the second direction, and a length of the scan line along the second direction is smaller than a length of the first fracture along the second direction.

4. The display substrate according to claim 1, wherein the dummy data line in the second circuit unit is electrically connected to a second voltage line extending in the second direction and transmitting a first voltage signal.

5. The display substrate according to claim 4, wherein in a direction perpendicular to the display substrate, the drive circuit layer comprises: a semiconductor layer, a first conductive layer, a second conductive layer, a third conductive layer, a fourth conductive layer, and a fifth conductive layer disposed on the base substrate; and
the scan line is located in the first conductive layer, the dummy data line and the first data line are located in the fifth conductive layer, and the second voltage line is located in the third conductive layer.

6. The display substrate according to claim 1, wherein the dummy data line in the second circuit unit is electrically connected to a third voltage line extending in the first direction and transmitting a second voltage signal.

7. The display substrate according to claim 6, wherein the drive circuit layer further comprises: a fourth voltage line extending in the second direction and transmitting the second voltage signal, wherein the fourth voltage line is located on a side of the third voltage line away from the base substrate and electrically connected to the third voltage line; and the dummy data line and the fourth voltage line are disposed in a same layer.

8. The display substrate according to claim 7, wherein in a direction perpendicular to the display substrate, the drive circuit layer comprises: a semiconductor layer, a first conductive layer, a second conductive layer, a third conductive layer, a fourth conductive layer, and a fifth conductive layer that are disposed on the base substrate; and
the third voltage line is located in the fourth conductive layer, and the dummy data line and the fourth voltage line are located in the fifth conductive layer.

9. The display substrate according to claim 1, wherein the first pixel circuit and the dummy pixel circuit each comprise at least: a drive transistor, a data writing transistor, and a threshold compensation transistor; gates of data writing transistors and threshold compensation transistors of the first pixel circuit and the dummy pixel circuit are electrically connected to the scan line;
a first electrode of the data writing transistor of the first pixel circuit is electrically connected to the first data line, and a second electrode of the data writing transistor of the first pixel circuit is electrically connected to a first electrode of the drive transistor of the first pixel circuit; a first electrode of the threshold compensation transistor of the first pixel circuit is electrically connected to a gate of the drive transistor of the first pixel circuit, and a second electrode of the threshold compensation transistor of the first pixel circuit is electrically connected to a second electrode of the drive transistor of the first pixel circuit;
a first electrode of the data writing transistor of the dummy pixel circuit is electrically connected to the dummy data line, and a second electrode of the data writing transistor of the dummy pixel circuit is electrically connected to a first electrode of the drive transistor of the dummy pixel circuit; a first electrode of the threshold compensation transistor of the dummy pixel circuit is electrically connected to a gate of the drive transistor of the dummy pixel circuit, and a second electrode of the threshold compensation transistor of the dummy pixel circuit is electrically connected to a second electrode of the drive transistor of the dummy pixel circuit;
the display substrate satisfies at least one of the following: the threshold compensation transistor of the first pixel circuit is a dual-gate structure, and the threshold compensation transistor of the dummy pixel circuit is a single-gate structure; a length of a gate of the data writing transistor of the first pixel circuit along the second direction is greater than a length of a gate of the data writing transistor of the dummy pixel circuit along the second direction.

10. The display substrate according to claim 9, wherein gates of data writing transistors and threshold compensation transistors of the first pixel circuit and the dummy pixel circuit and the scan line are an interconnected integral structure.

11. The display substrate according to claim 1, wherein the first pixel circuit and the dummy pixel circuit each comprise: a drive transistor, a first reset transistor, a threshold compensation transistor, and a storage capacitor;
a gate of the drive transistor, a second electrode of the first reset transistor, a first electrode of the threshold compensation transistor and a first plate of the storage capacitor, of the first pixel circuit are electrically connected with a second connection electrode; an orthographic projection of the second connection electrode on the base substrate is partially overlapped with an orthographic projection of the scan line on the base substrate; and
a gate of the drive transistor and a first plate of the storage capacitor, of the dummy pixel circuit are electrically connected to a ninth connection electrode, a second electrode of the first reset transistor and a first electrode of the threshold compensation transistor, of the dummy pixel circuit are electrically connected to a tenth connection electrode, and the ninth connection electrode and the tenth connection electrode are located at two sides of the scan line, and orthographic projections of the ninth connection electrode and the tenth connection electrode on the base substrate do not overlap with an orthographic projection of the scan line on the base substrate.

12. The display substrate according to claim 11, wherein the ninth connection electrode and the tenth connection electrode are both electrically connected to a second voltage line extending in the second direction and transmitting a first voltage signal.

13. The display substrate according to claim 11, wherein the first pixel circuit further comprises: a first shielding electrode located on a side of the second connection electrode away from the base substrate, an orthographic projection of the first shielding electrode on the base substrate covers an orthographic projection of the second connection electrode on the base substrate; and
the dummy pixel circuit further comprises a second shielding electrode located on a side of the ninth connection electrode and the tenth connection electrode away from the base substrate, and an orthographic projection of the second shielding electrode on the base substrate covers orthographic projections of the ninth connection electrode and the tenth connection electrode on the base substrate.

14. The display substrate according to claim 11, wherein the first pixel circuit further comprises: a first shielding electrode located on a side of the second connection electrode away from the base substrate, an orthographic projection of the first shielding electrode on the base substrate covers an orthographic projection of the second connection electrode on the base substrate; and
the dummy pixel circuit further comprises: a third shielding electrode and a fourth shielding electrode located on a side of the ninth connection electrode and the tenth connection electrode away from the base substrate; an orthographic projection of the third shielding electrode on the base substrate covers an orthographic projection of the ninth connection electrode on the base substrate, an orthographic projection of the fourth shielding electrode on the base substrate covers an orthographic projection of the tenth connection electrode on the base substrate, and orthographic projections of the third shielding electrode and the fourth shielding electrode on the base substrate do not overlap with the orthographic projection of the scan line on the base substrate.

15. The display substrate according to claim 14, wherein the third shielding electrode is electrically connected to a third voltage line extending in the first direction and transmitting a second voltage signal; the fourth shielding electrode is electrically connected to a second voltage line extending in the second direction and transmitting a first voltage signal, and the first voltage signal is greater than the second voltage signal.

16. The display substrate according to claim 1, wherein the plurality of circuit units further comprises: a plurality of second pixel circuits; at least one of the second pixel circuits and the dummy pixel circuit are located in a same unit column;
the base substrate further comprises: a second display region located on at least one side of the first display region; and the light emitting structure layer further comprises: a plurality of second light emitting elements located in the second display region; and
at least one of the second pixel circuits is connected with at least one second light emitting element through a conductive connection line.

17. A display apparatus, comprising the display substrate according to claim 1, and a sensor located on a non-display side of the display substrate; an orthographic projection of the sensor on the display substrate is at least partially overlapped with a second display region of the display substrate.

18. The display substrate according to claim 16, wherein a light emitting area of a single second light emitting element is smaller than a light emitting area of a single first light emitting element.

19. The display substrate according to claim 16, wherein a plurality of first pixel circuits are arranged between two second pixel circuits adjacent in the first direction, and a plurality of first pixel circuits are arranged between two adjacent dummy pixel circuits.

20. The display substrate according to claim 1, wherein circuit structures of the first pixel circuit and the dummy pixel circuit are both a 7T1C structure.
